(19) United States
(12) Patent Application Publication
(10) Pub. No.: US 2007/0176516 A1
(43) Pub. Date: Aug. 2, 2007

(54) Piezoelectric sensor

(75) Inventors: Toshiatsu Nagaya, Kuwana-shi (JP); Tatsuhiko Nonoyama, Chiryu-shi (JP); Masaya Nakamura, Nagoya-shi (JP); Yasuyoshi Saito, Toyota-shi (JP); Hisaaki Takao, Seto-shi (JP); Takahiko Homma, Nagoya-shi (JP); Kazumasa Takatori, Nagoya-shi (JP)

Correspondence Address: HARNESS, DICKEY & PIERCE, P.L.C., P.O. BOX 828, BLOOMFIELD HILLS, MI, 48303, US

(73) Assignee: Denso Corporation, Kariya-City (JP)

(21) Appl. No.: 11/715,744

(22) Filed: Mar. 8, 2007

Related U.S. Application Data
(63) Continuation of application No. PCT/JP05/17227, filed on Sep. 13, 2005.

(30) Foreign Application Priority Data
Sep. 13, 2004 (JP) 2004-266112
Aug. 5, 2005 (JP) 2005-228398

(51) Int. Cl. H01L 41/00

(52) U.S. Cl. 310/346

(57) ABSTRACT

A piezoelectric sensor capable of preventing fluctuation in the sensitivity of the piezoelectric sensor over a wide temperature range is provided. This is a piezoelectric sensor comprising a piezoelectric element and a holding member for holding the piezoelectric element, the piezoelectric element comprising a piezoelectric ceramic having formed on the surfaces thereof a pair of electrodes. The piezoelectric ceramic satisfies the following requirement (a) and/or requirement (b): (a) in the temperature range from −30° C. to 160° C., the thermal expansion coefficient is 3.0 ppm/° C. or more, and
(b) in the temperature range from −30° C. to 160° C., the pyroelectric coefficient is 400 μCm⁻²K⁻¹ or less.

### CROSS-REFERENCE TO RELATED APPLICATIONS

This application is based and claims priority of Japanese Patent Applications Nos. 2004-266112, filed Sep. 13, 2004 and 2005-228398, filed Aug. 5, 2005, each of which are hereby incorporated by reference, and is a Continuation of PCT/JP2005/-17227, the contents being incorporated herein.

### TECHNICAL FIELD

The present invention relates to a piezoelectric sensor making use of a piezoelectric effect and including, for example, a pressure sensor, an acceleration sensor, a knock sensor, a yaw rate sensor, a gyro sensor and a shock sensor.

### BACKGROUND ART

The piezoelectric sensor using a piezoelectric ceramic material is a product for converting mechanical energy into electrical energy, by utilizing the piezoelectric effect, and is widely applied in the field of electronics or mechatronics.

The piezoelectric sensor generates an electric charge or voltage upon receipt of a stress, which should be detected, by a piezoelectric element incorporated into the piezoelectric sensor, and sends the generated electric charge or voltage to a circuit connected to the sensor or a circuit integrated with the sensor, whereby the detected stress is converted into a voltage signal.

The piezoelectric sensor generally comprises at least a piezoelectric element comprising a piezoelectric ceramic and having a pair of electrodes provided thereon, a holding part for holding the piezoelectric element, an adhesive member or press-contact member (e.g., a spring) for keeping the piezoelectric element in the holding part, and a lead terminal for taking out an electric signal from the piezoelectric element.

In the piezoelectric sensor, the piezoelectric element is joined with an adhesive or press-contacted by a mold, a spring or the like and therefore, a mechanical binding force (a preset load) is imposed in the assembled state.

The temperature range in which the piezoelectric sensor is used greatly differs depending on the kind of the piezoelectric sensor product. However, it is known that the lower limit of the temperature range in use is −40° C. or more and the upper limit is about 160° C. or less.

When the temperature in the use environment of a piezoelectric sensor is changed, this sometimes causes fluctuation in the sensitivity of the piezoelectric sensor.

That is, there is a problem that, when the temperature of a piezoelectric sensor is changed, the piezoelectric characteristics, and the like, of the piezoelectric ceramic are changed and, as a result, the sensitivity (output voltage) of the piezoelectric sensor fluctuates as described above.

In order to solve this problem, Kokai (Japanese Unexamined Patent Publication) No. 5-284600 discloses a piezoelectric element in which a temperature compensation capacitor is electrically connected, in series or in parallel, to a piezoelectric ceramic. In a pressure sensor using this piezoelectric element, fluctuation of the output voltage can be reduced in the temperature range from 20° C. to 150° C.

Also, Kokai No. 7-79022 discloses a piezoelectric element fabricated by alternately stacking a piezoelectric layer and a dielectric layer and using materials ensuring that the electrostatic capacitance of the dielectric layer is larger than the electrostatic capacitance of the piezoelectric layer and the temperature coefficient of the dielectric layer is opposite the temperature coefficient of the piezoelectric layer. In a pressure sensor using this piezoelectric element, the temperature characteristics of the piezoelectric d33 constant and piezoelectric g33 constant are improved in the temperature region from 0° C. to about 150° C. In turn, the fluctuation due to temperature change of the pressure sensor can be reduced.

However, in use as automobile part, the piezoelectric sensor is sometimes used in a wide temperature range of from −40° C. to 160° C., and a piezoelectric sensor free from fluctuation in the temperature characteristic over a wider temperature range is in demand.

Also, when the temperature of a piezoelectric sensor is changed resulting from a temperature change in the use environment or a temperature increase due to driving, a thermal expansion difference may arise between the piezoelectric ceramic constituting the piezoelectric element and the other member in contact with the piezoelectric ceramic, such as an electrode and a holding member. This causes a problem that a thermal stress is generated and the thermal stress brings about noise in the piezoelectric sensor. As a result, the sensitivity fluctuates.

Furthermore, when the temperature of a piezoelectric sensor is changed, a voltage is sometimes generated in the piezoelectric sensor by the pyroelectric effect. This voltage due to the pyroelectric effect also generates noise in the piezoelectric sensor to change the sensitivity.

### DISCLOSURE OF THE INVENTION

The present invention has been made by taking account of these conventional problems and an object of the present invention is to provide a piezoelectric sensor ensuring that a fluctuation in the sensitivity of the piezoelectric sensor can be suppressed over a wide temperature range.

The present invention is a piezoelectric sensor comprising a piezoelectric element, a transmitting member for transmitting an external stress to the piezoelectric element, and a holding member for holding the piezoelectric element, the piezoelectric element comprising a piezoelectric ceramic having formed on the surfaces thereof a pair of electrodes, wherein

the piezoelectric ceramic satisfies the following requirement (a) and/or requirement (b):

(a) in the temperature range from −30° C. to 160° C., the thermal expansion coefficient is 3.0 ppm/° C. or more, and

(b) in the temperature range from −30° C. to 160° C., the pyroelectric coefficient is 400 μCm⁻²K⁻¹ or less.

In the piezoelectric sensor of the present invention, the piezoelectric ceramic satisfies the requirement (a) and/or the requirement (b). That is, in the piezoelectric sensor of the present invention, the piezoelectric ceramic satisfies either the requirement (a) or the requirement (b) or satisfies both the requirements (a) and (b). Therefore, the piezoelectric sensor of the present invention can be free from fluctuation in the sensitivity of the piezoelectric sensor over a wide temperature range from −30° C. to 160° C.

In the case where the piezoelectric ceramic satisfies the requirement (a), the thermal expansion difference between the piezoelectric ceramic and other member in contact with the piezoelectric ceramic, such as electrode and holding member, can be reduced. Therefore, the thermal stress due to thermal expansion difference generated between the piezoelectric ceramic and other member can be prevented from occurring even when the temperature of the piezoelectric element changes resulting from, for example, a temperature change in the use environment or a temperature increase on driving. In turn, generation of a fluctuation in the sensitivity (output voltage) of the piezoelectric sensor due to a thermal stress can be prevented. Furthermore, generation of noise or the like due to a thermal stress can be prevented. In addition, when the requirement (a) is satisfied, since generation of a thermal stress can be prevented as described above, the piezoelectric sensor can be prevented from being broken down by thermal stress.

In general, a piezoelectric sensor, such as a pressure sensor, an acceleration sensor, a yaw rate sensor, a gyro sensor and a shock sensor, is used by heat-bonding it to another member at a high temperature and therefore, the above-described problems due to generation of a thermal stress readily occur. Accordingly, when a piezoelectric sensor satisfying the requirement (a) is used for a pressure sensors an acceleration sensor, a yaw rate sensor, a gyro sensor, a shock sensor or the like, the effect of suppressing a thermal stress can be more remarkably exerted.

Also, a piezoelectric sensor such as knock sensor is used in a high-temperature environment reaching a maximum temperature of about 150° C. by, for example, integrally fixing the piezoelectric element comprising a piezoelectric ceramic to a mold such as resin at a high temperature of 200° C. or more and installing it in the engine of an automobile. Accordingly, when the piezoelectric sensor satisfying the requirement (a) is used for a knock sensor or the like, the above-described excellent effect of suppressing a thermal stress can be more remarkably exerted.

In the case where the piezoelectric ceramic satisfies the requirement (b), the pyroelectric effect can be made to less occur even when the temperature change is caused in the piezoelectric sensor. Therefore, the piezoelectric sensor can be prevented from generation of a voltage due to pyroelectric effect, generation of fluctuation in the sensitivity (output voltage) of the piezoelectric sensor, and generation of noise in the piezoelectric sensor.

In the conventional piezoelectric sensor, in order to avoid the occurrence of the pyroelectric effect, a short-circuit is established between electrode terminals of the piezoelectric sensor by a metal clipping jig or the like or the product form is changed to place a resistor between electrode terminals. When the piezoelectric ceramic satisfies the requirement (b), generation of the pyroelectric effect can be suppressed and such a step or part conventionally used for preventing the pyroelectric effect need not be additionally provided during production. Accordingly, the production cost of the piezoelectric sensor can be reduced.

In general, the piezoelectric element is a stack type where a plurality of piezoelectric ceramics and a plurality of electrodes are alternately stacked. For example, in a piezoelectric sensor such as a stacked pressure sensor, a stacked acceleration sensor, a stacked yaw rate sensor, a stacked gyro sensor and a stacked shock sensor, the electric charge generated by the pyroelectric effect increases. Accordingly, when the piezoelectric sensor having a stacked piezoelectric element satisfies the requirement (b), the effect of suppressing the electric charge generation attributable to the pyroelectric effect can be more remarkably exerted.

Also, in a piezoelectric sensor such as a knock sensor, a piezoelectric element having a plate thickness of, for example, 2 mm or more is generally used and the electric charge generated by the pyroelectric effect tends to increase. Therefore, in a knock sensor or the like, for example, a short-circuiting resistor is generally provided so as to reduce the electric charge generation. Accordingly, when a piezoelectric sensor satisfying the requirement (b) is used for a knock sensor, not only the above-described operational effect of reducing the electric charge generated due to pyroelectric effect can be more remarkably exerted but also a short-circuiting resistor or the like can be dispensed with.

In this way, according to the present invention, a piezoelectric sensor capable of preventing fluctuation in the sensitivity of the piezoelectric sensor over a wide temperature range can be provided. Also, a piezoelectric sensor more inexpensive than a piezoelectric sensor made by a conventional technique can be provided.

### BRIEF DESCRIPTION OF THE DRAWINGS

FIG. 1 is a diagram showing the temperature characteristic of the piezoelectric constant g₃₁ in each of the piezoelectric elements produced in Examples 4 and 5 and Comparative Example 1.

FIG. 2 is a diagram showing the temperature characteristic of the piezoelectric constant d₃₁ in each of the piezoelectric elements produced in Examples 4 and 5 and Comparative Example 1.

FIG. 3 is a diagram showing the temperature characteristic of the dielectric loss (tan δ) of the piezoelectric element produced in Example 5.

FIG. 4 is a diagram showing the temperature characteristic of the linear thermal expansion coefficient in each of the piezoelectric ceramics produced in Example 2 and Comparative Example 1.

FIG. 5 is a diagram showing the temperature characteristic of the variation in the polarized amount Pr of each of the piezoelectric elements produced in Example 4 and Comparative Example 1.

FIG. 6 is a diagram showing the relationship between the breakdown probability and 1 nF in each of the piezoelectric ceramics produced in Examples 5 and Comparative Example 1.

FIG. 7 is an explanatory view showing the construction of a piezoelectric sensor.

FIG. 8 is an exploded explanatory view of a piezoelectric sensor.

FIG. 9 is a diagram showing the temperature characteristic of the electrostatic capacitance in each of the piezoelectric elements produced in Example 11 and Comparative Example 6.

FIG. 10 is a circuit diagram showing the measuring method for the output voltage of a piezoelectric sensor.

FIG. 11 is a diagram showing the temperature characteristic of the output voltage in each of the piezoelectric sensors produced in Example 11 and Comparative Example 6.

### BEST MODE FOR CARRYING OUT THE INVENTION

The embodiments of the present invention will be described below.

The piezoelectric sensor of the present invention comprises a piezoelectric element and a holding member.

More specifically, the piezoelectric element may be composed of, for example, a piezoelectric ceramic and a pair of electrodes formed to sandwich the piezoelectric ceramic.

Also, the piezoelectric element may be a stacked piezoelectric element obtained by alternately stacking a plurality of piezoelectric ceramics and a plurality of electrodes.

The holding member holds the piezoelectric element and, for example, fixing by a bolt or the like may be employed.

In the piezoelectric element for use in the piezoelectric sensor of the present invention, the piezoelectric ceramic satisfies the requirement (a) and/or requirement (b).

The requirement (a) is that, in a temperature range from −30° C. to 160° C., the thermal expansion coefficient is 3.0 ppm/° C. or more.

If the thermal expansion coefficient of the piezoelectric ceramic is less than 3.0 ppm/° C. in the above-described temperature range, a thermal stress may be readily generated in the piezoelectric sensor and in turn, the fluctuation in the sensitivity of the piezoelectric sensor due to temperature change may be increased. Also, the piezoelectric sensor may be easily broken down by the thermal stress.

The thermal expansion coefficient of the piezoelectric ceramic is preferably 3.5 ppm/° C. or more, more preferably 4.0 ppm/° C. or more. Incidentally, if the thermal expansion coefficient of the piezoelectric ceramic becomes larger than the thermal expansion coefficient of the metal member such as Fe constituting the piezoelectric sensor, generation of a thermal stress readily occurs therebetween. Therefore, the upper limit of the thermal expansion coefficient of the piezoelectric ceramic is preferably 11 ppm/° C. or less.

The thermal expansion coefficient of the piezoelectric ceramic may be determined, for example, according to the following formula by measuring the linear thermal expansion by TMA (thermal mechanical analysis) method.
β=(1/L₀)×(dL/dT)
wherein β is the linear thermal expansion coefficient [10⁻⁶/° C.], L₀ is the sample length [m] at the reference temperature (25° C.), dT is the temperature difference [° C.], and dL is the expansion length [m] at the temperature difference dT.

The requirement (b) is that the pyroelectric coefficient is 400 μCm⁻²K⁻¹ or less in the temperature range from −30° C. to 160° C.

If the pyroelectric coefficient of the piezoelectric ceramic exceeds 400 μCm⁻²K⁻¹ in the above-described temperature range, the pyroelectric effect readily occurs and a voltage may be generated in the piezoelectric sensor due to the temperature change, as a result, the sensitivity of the piezoelectric sensor may fluctuate.

The pyroelectric coefficient of the piezoelectric ceramic in the temperature range from −30° C. to 160° C. is preferably 350 μCm⁻²K⁻¹ or less, more preferably 300 μCm⁻²K⁻¹ or less.

The pyroelectric coefficient is an average temperature coefficient of the polarized amount when the piezoelectric ceramic is polarized. The pyroelectric coefficient can be measured, for example, by the following method.

The pyroelectric coefficient γ, which is represented by the definition expression:
γ=dP/dT [Cm⁻²K⁻¹]
(wherein P is the polarized amount and T is the temperature), can be usually determined by using measurable parameters, current I, sample electrode surface S, temperature change dT and measurement time interval dt, according to the following formula:
γ=(I/S)×(dt/dT) [Cm⁻²K⁻¹]

More specifically, the piezoelectric element is placed in a constant-temperature bath or an electric furnace and by elevating or lowering the temperature at a constant rate, the current I [A] flowing out from the electrodes on the top and bottom surfaces of the piezoelectric element is measured by a microammeter. The current is integrated by the measurement interval t [s], and the generated electric charge amount [C] is calculated. Then, the electric charge amount is divided by the electrode area of the piezoelectric element to determine the temperature characteristic of the polarized amount P (C/cm²) at each temperature, and the temperature coefficient is calculated from the values obtained (pyroelectric current method).

The piezoelectric ceramic which can be used in the piezoelectric sensor of the present invention preferably satisfies both the requirement (a) and the requirement (b).

In this case, the reliability of the piezoelectric sensor can be enhanced by reducing the temperature dependency of the sensitivity of the piezoelectric sensor.

In another embodiment, the piezoelectric ceramic which can be used in the piezoelectric sensor of the present invention preferably satisfies the condition that the piezoelectric constant g₃₁ in the temperature range from −30° C. to 80° C. is 0.006 Vm/N or more and the fluctuation width of the piezoelectric constant g₃₁ in the temperature range from −30° C. to 80° C. is within ±15%.

In still another embodiment, the piezoelectric ceramic which can be used in the piezoelectric sensor of the present invention preferably satisfies the condition that the piezoelectric constant d₃₁ in the temperature range from −30° C. to 80° C. is 70 pC/N or more and the fluctuation width of said piezoelectric constant d₃₁ in the temperature range from −30° C. to 80° C. is within ±15%.

According to these embodiments, in the working temperature range of the piezoelectric sensor, the sensitivity of the piezoelectric sensor can be enhanced and at the same time, fluctuation in the sensitivity of the piezoelectric sensor due to a temperature change can be reduced.

The reasons why such effects can be obtained are considered to be as follows.

In the case where the circuit connected to the piezoelectric sensor is a charge amplifier, when the charge amplifier is fabricated such that the equivalent input resistance of the charge amplifier becomes about 10Ω or less, this serves as a circuit capable of measuring the electric flux density D generated due to a stress produced in the piezoelectric sensor. In this case, a circuit voltage output proportional to the electric charge sensor coefficient d is obtained. Also, even in the case where the circuit connected to the piezoelectric sensor is not a charge amplifier, when a capacitor having a capacitance 10 times or more larger than that of the piezoelectric element is connected in parallel and the voltage is measured at both ends thereof, the circuit output voltage is nearly proportional to the electric charge sensor coefficient d. The electric charge sensor coefficient d is proportional to the piezoelectric d constant of the piezoelectric material.

Furthermore, in the case where the circuit connected to the piezoelectric sensor is a voltage amplifier (e.g., buffer amplifier), when the buffer amplifier is composed of an op-amp or FET (field effect transistor) having an input resistance of about 10¹²Ω or more, the current flowing into the circuit from the piezoelectric element can be made to be nearly zero and, as a result, the generated electric charge is held on the piezoelectric element surface for a long time and the circuit output voltage becomes proportional to the electric charge sensor coefficient g. The electric charge sensor coefficient g is proportional to the piezoelectric g constant of the piezoelectric material.

The resistance of the circuit is usually from 10 kΩ to 100 MΩ and, in this case, the circuit output voltage shows an intermediate characteristic between the circuit output voltage nearly proportional to the electric charge sensor coefficient d and the circuit output voltage proportional to the electric charge sensor coefficient g.

More specifically, depending on the size of the circuit input resistance, the circuit output may be proportional to the d constant of the piezoelectric element, proportional to the g constant, or proportional to the intermediate characteristic between the d constant and the g constant.

Accordingly, as described above, when the piezoelectric sensor is fabricated to have a piezoelectric constant g₃₁ of 0.006 Vm/N or more or a piezoelectric constant d₃₁ or 70 pC/N or more, the sensitivity of the piezoelectric sensor can be increased. Also, when the fluctuation width of the piezoelectric constant g₃₁ or piezoelectric constant d₃₁ with respect to the temperature change is made to fall within the above-described range, fluctuation in the sensitivity of the piezoelectric sensor due to a temperature change can be reduced.

In the piezoelectric sensor, if the piezoelectric constant g₃₁ in the above-described specific temperature range is less than 0.006 Vm/N or the piezoelectric constant d₃₁ is less than 70 pC/N, the sensitivity of the piezoelectric sensor may be deteriorated. Also, if the fluctuation width of the piezoelectric constant g₃₁ in the above-described specific temperature range deviates from the range of ±15% or if the fluctuation width of the piezoelectric constant d₃₁ in the above-described specific temperature range deviates from the range of ±15%, the sensitivity of the piezoelectric sensor greatly fluctuates due to temperature change.

In another embodiment, the piezoelectric ceramic which can be used in the piezoelectric sensor of the present invention preferably satisfies the condition that the piezoelectric constant g₃₁ in the temperature range from −30° C. to 160° C. is 0.006 Vm/N or more and the fluctuation width of the piezoelectric constant g₃₁ in the temperature range from −30° C. to 160° C. is within ±15%.

In still another embodiment, the piezoelectric ceramic which can be used in the piezoelectric sensor of the present invention preferably satisfies the condition that the piezoelectric constant d₃₁ in the temperature range from −30° C. to 160° C. is 70 pC/N or more and the fluctuation width of the piezoelectric constant d₃₁ in the temperature range from −30° C. to 160° C. is within ±15%.

According to these embodiments, the piezoelectric sensor can exert high sensitivity in a wider temperature range from −30° C. to 160° C. and, at the same time, the dependency of the sensitivity on the temperature change can be reduced.

The piezoelectric sensor of the present invention is preferably used for a knock sensor. When the piezoelectric sensor of the present invention is used for a knock sensor, the excellent characteristics of the piezoelectric sensor can be used to advantage.

Also, the piezoelectric sensor of the present invention may be used for a pressure sensor, an acceleration sensor, a yaw rate sensor, a gyro sensor or a shock sensor.

The piezoelectric element which can be used in the piezoelectric sensor of the present invention is preferably a stacked piezoelectric element obtained by alternately stacking the above-described piezoelectric ceramic and electrode.

In this case, the operational effect of allowing for less occurrence of the pyroelectric effect by virtue of the requirement (b) can be more remarkably brought out.

Generally, in the case of using a stacked piezoelectric element, the generated electric charge due to the pyroelectric effect is liable to increase and short-circuiting readily occurs. However, in the present invention, the requirement (b) is satisfied, so that even when a stacked piezoelectric element is used, generation of the pyroelectric effect can be suppressed.

The stacked piezoelectric element has a structure that a piezoelectric ceramic and an electrode are alternately stacked. Specific examples thereof include those having an integrally-fired electrode structure formed by firing a stacked body where a plurality of unfired piezoelectric ceramics and a plurality of electrodes are alternately stacked, and those having a structure formed by preparing a plurality of piezoelectric elements, each comprising a fired piezoelectric ceramic having formed thereon an electrode, and joining the plurality of piezoelectric elements by adhesion.

The piezoelectric ceramic which can be used for the piezoelectric sensor of the present invention preferably comprises a piezoelectric ceramic not containing lead.

In this case, the safety of the piezoelectric sensor in the environment can be enhanced.

The piezoelectric ceramic which can be used for the piezoelectric sensor of the present invention preferably comprises a crystal-oriented piezoelectric ceramic comprising a polycrystalline body in which the main phase is an isotropic perovskite-type compound represented by the formula:
{Liₓ(K_{1-y}Na_{y})₁₋ₓ}{Nb_{1-z-w}Ta_{z}Sb_{w}}O₃
(wherein 0≦x≦0.2, 0≦y≦1, 0≦z≦0.4, 0≦w≦0.2 and x+z+w>0) and a specific crystal plane of each crystal grain constituting the polycrystalline body is oriented.

In this case, a piezoelectric sensor satisfying the requirements (a) and (b) can be easily realized.

The crystal-oriented piezoelectric ceramic has a fundamental composition of potassium sodium niobate (K_{1-y}Na_{y}NbO₃), which is a kind of isotropic perovskite-type compound, where a part of the A-site elements (K and Na) is replaced by a predetermined amount of Li and/or a part of the B-site element (Nb) is replaced by a predetermined amount of Ta and/or Sb. In the formula above, “x+z+w>0” means that it is sufficient if at least one member of Li, Ta and Sb is contained as the replacing element.

Also, in the formula above, “y” represents the ratio of K and Na contained in the crystal-oriented piezoelectric ceramic. The crystal-oriented piezoelectric ceramic for use in the present invention may suffice if at least either K or Na is contained as the A-site element. That is, the ratio y of K and Na is not particularly limited and may take an arbitrary value of 0 to 1. In order to obtain a high displacement characteristic, the value of y is preferably from 0.05 to 0.75, more preferably from 0.20 to 0.70, still more preferably from 0.35 to 0.65, yet still more preferably from 0.40 to 0.60, and most preferably from 0.42 to 0.60.

“x” represents the replacement ratio of Li replacing K and/or Na which are an A-site element. When a part of K and/or Na is replaced by Li, this allows for enhancement of the piezoelectric characteristics and the like, elevation of the Curie temperature, and/or acceleration of densification. Specifically, x preferably takes a value of 0 to 0.2. If the value of x exceeds 0.2, the displacement characteristic decreases and this is not preferred. The value of x is preferably from 0 to 0.15, more preferably from 0 to 0.10.

“z” represents the replacement ratio of Ta replacing Nb which is a B-site element. When a part of Nb is replaced by Ta, this allows for enhancement of the piezoelectric characteristics and the like. Specifically, the value of z is preferably from 0 to 0.4. If the value of z exceeds 0.4, the Curie temperature decreases and this is not preferred because utilization as a piezoelectric material for home appliances or automobiles becomes difficult. The value of z is preferably from 0 to 0.35, more preferably from 0 to 0.30.

“w” represents the replacement ratio of Sb replacing Nb which is a B-site element. When a part of Nb is replaced by Sb, this allows for enhancement of the piezoelectric characteristics and the like. Specifically, the value of w is preferably from 0 to 0.2. If the value of w exceeds 0.2, the displacement characteristic and/or the Curie temperature decrease and this is not preferred. The value of w is more preferably from 0 to 0.15.

In the crystal-oriented piezoelectric ceramic, when it is cooled from a high temperature to a low temperature, the crystal phase changes from cubic to tetragon (first crystal phase transition temperature=Curie temperature), from tetragon to orthorhombic (second crystal phase transition temperature), and from orthorhombic to rhombohedral (third crystal phase transition temperature). In the temperature region higher than the first crystal phase transition temperature, the crystal phase becomes cubic and the piezoelectricity is lost. Also, in the temperature region lower than the second crystal phase transition temperature, the crystal phase becomes orthorhombic and the temperature dependency of the piezoelectric constants d₃₁ and g₃₁ increases. Accordingly, it is preferred to have a first crystal phase transition temperature higher than the working temperature range and a second crystal phase transition temperature lower than the working temperature range, so that the crystal phase can be tetragon over the entire region in the working temperature range.

However, in the potassium sodium niobate (K_{1-y}Na_{y}NbO₃) which is the fundamental composition of the crystal-oriented piezoelectric ceramic, as described in Journal of American Ceramic Society, Vol. 42[9], pp. 438-442, U.S.A. (1959) and U.S. Pat. No. 2,976,246, when the temperature changes from a high temperature to a low temperature, the crystal phase changes from cubic to tetragon (first crystal phase transition temperature=Curie temperature), from tetragon to orthorhombic (second crystal phase transition temperature), and from orthorhombic to rhombohedral (third crystal phase transition temperature). Also, when “y=0.5”, the first crystal phase transition temperature is about 420° C., the second crystal phase transition temperature is about 190° C., and the third crystal phase transition temperature is about −150° C. Accordingly, the temperature region in which the crystal phase is tetragon is from 190° C. to 420° C. and disagrees with the working temperature range of an industrial product, which is from −40° C. to 160° C.

On the other hand, in the crystal-oriented piezoelectric ceramic according to the present invention, the first crystal phase transition temperature and the second crystal phase transition temperature can be freely controlled by varying the amount of the replacing element Li, Ta or Sb based on the potassium sodium niobate (K_{1-y}Na_{y}NbO₃) as the fundamental composition.

With respect to y=0.4 to 0.6 of giving largest piezoelectric characteristics, a multiple regression analysis of the replacement amount of Li, Ta or Sb and the crystal phase transition temperature found was performed. The results are shown in the following formulae B1 and B2.

It can be seen from formulae B1 and B2 that the increase of Li replacement amount has an activity of increasing the first crystal phase transition temperature and decreasing the second crystal phase transition temperature. Also, the increase in the replacement amount of Ta or Sb has an activity of decreasing the first crystal phase transition temperature and decreasing the second phase transition temperature.
First crystal phase transition temperature=(388+9x−5z−17w)±50 [° C.] (formula B1)
Second crystal phase transition temperature=(190−18.9x−3.9z−5.8w)±50 [° C.] (formula B2)

The first crystal phase transition temperature is a temperature where the piezoelectricity is completely lost, and in the vicinity thereof, the dynamic capacitance abruptly increases. Therefore, the first crystal phase transition temperature is preferably not lower than (upper limit temperature in use environment of product +60° C.). The second crystal phase transition temperature is a temperature where crystal phase transition merely proceeds and, as the piezoelectricity is not lost, this temperature may be set to a range of not causing an adverse effect on the temperature dependency of the sensor output. Accordingly, the second crystal phase transition temperature is preferably not higher than (lower limit temperature in use environment of product +40° C.).

On the other hand, the upper limit temperature in use environment of product varies depending on the usage and is, for example, 60° C., 80° C., 100° C., 120° C., 140° C. or 160° C. The lower limit temperature in use environment of product is, for example, −30° C. or −40° C.

Accordingly, the first crystal phase transition temperature represented by formula B1 is preferably 120° C. or more and, in turn, the values of “x”, “z” and “w” preferably satisfy the formula: (388+9x−5z−17w)±50≧120.

Also, the second crystal phase transition temperature represented by formula B2 is preferably 10° C. or less and in turn, the values of “x”, “z” and “w” preferably satisfy the formula: (190−18.9x−3.9z−5.8w)−50≦10.

That is, in the crystal-oriented piezoelectric ceramic, x, y and z in the formula, {Liₓ(K_{1-y}Na_{y})₁₋ₓ}{Nb_{1-z-w}Ta_{z}Sb_{w}}O₃, preferably satisfy the relationships of the following formulae (1) and (2):
9x−5z−17w≧−318 (1)
−18.9x−3.9z−5.8w≦−130 (2)

Incidentally, the crystal-oriented piezoelectric ceramic according to the present invention include a case where the ceramic comprises only an isotropic perovskite-type compound represented by the formula above (first KNN-based compound), and a case where another element is aggressively added or used for replacement.

In the former case, the ceramic preferably comprises only the first KNN-based compound but as long as the isotropic perovskite-type crystal structure can be maintained and at the same time, various properties such as a sintering characteristic and a piezoelectric characteristic are not adversely affected, other element or phase may be contained. Particularly, in the raw material used for producing the crystal-oriented piezoelectric ceramic, an impurity contained in an industrial raw material having a purity of 99 to 99.9% available on the market is inevitably mingled. For example, in Nb₂O₅ as one of raw materials for the crystal-oriented piezoelectric ceramic, Ta up to less than 0.1 wt % and F up to less than 0.15 wt % are contained as impurities originated in the crude ore or production process. Furthermore, as described in Example 1 later, in the case of using Bi in the production process, this is inevitably mingled.

In the crystal-oriented piezoelectric ceramic, a specific crystal plane of each crystal grain constituting the polycrystalline body where the main phase is the isotropic perovskite-type compound represented by the formula above, is oriented. The oriented specific crystal plane of the crystal grain is preferably a pseudo-cubic {100} plane.

Incidentally, the “pseudo-cubic {HKL}” means that although the isotropic perovskite-type compound generally takes a structure slightly distorted from cubic, such as tetragon, orthorhombic or trigonal, the distortion is slight and therefore, the structure is regarded as a cubic crystal and expressed by the mirror index.

When this plane is oriented, d₃₁ and g₃₁ of the piezoelectric sensor can be increased and the temperature dependency of d₃₁ and g₃₁ can be reduced.

In the case where the pseudo-cubic {100} plane is plane-oriented, the degree of plane orientation can be expressed by an average orientation degree F(HKL) according to the Lotgering's method represented by the following mathematical formula (Math. 1):

$$F ( HKL ) = \frac{\frac{{\sum }^{′} I ( HKL )}{\sum I ( hkl )} - \frac{{\sum }^{′} {I}_{0} ( HKL )}{\sum {I}_{0} ( hkl )}}{1 - \frac{{\sum }^{′} {I}_{0} ( HKL )}{\sum {I}_{0} ( hkl )}} \times 100 ( \% ) \qquad ( Math . 1 )$$

In the mathematical formula (Math. 1), ΣI(hkl) is a sum total of X-ray diffraction intensities of all crystal planes (hkl) measured in the crystal-oriented piezoelectric ceramic, ΣI₀(hkl) is a sum total of X-ray diffraction intensities of all crystal planes (hkl) measured in a non-oriented ceramic having the same composition as the crystal-oriented piezoelectric ceramic, Σ′I(HKL) is a sum total of X-ray diffraction intensities of crystallographically equivalent specific crystal planes (HKL) measured in the crystal-oriented piezoelectric ceramic, and Σ′I₀(HKL) is a sum total of X-ray diffraction intensities of crystallographically equivalent specific crystal planes (HKL) measured in a non-oriented ceramic having the same composition as the crystal-oriented piezoelectric ceramic.

Accordingly, when each crystal grain constituting the polycrystalline body is non-oriented, the average orientation degree F(HKL) becomes 0%, whereas when the (HKL) plane of all crystal grains constituting the polycrystalline body is oriented in parallel to the measurement plane, the average orientation degree F(HKL) becomes 100%.

In general, as the ratio of oriented crystal grains is larger, higher characteristics are obtained. For example, in the case of plane-orienting a specific crystal plane, for obtaining high piezoelectric characteristics or the like, the average orientation degree F(HKL) as measured according to the Lotgering's method represented by mathematical formula (Math. 1) is preferably 30% or more, more preferably 50% or more, still more preferably 70% or more. The specific crystal plane to be oriented is preferably a plane perpendicular to the polarization axis. For example, when the crystal system of the perovskite-type compound is tetragon, the specific-crystal plane to be oriented is preferably a pseudo-cubic {100} plane.

That is, it is preferred that, in the crystal-oriented piezoelectric ceramic, the orientation degree of the pseudo-cubic {100} plane according to the Lotgering's method is 30% or more and in the temperature range from 10° C. to 160° C., the crystal system is tetragon.

Incidentally, in the case of axis-orienting a specific crystal plane, the orientation degree thereof cannot be defined by the same orientation degree (formula of Math. 1) as the plane orientation, but the degree of axis orientation can be expressed by using an average orientation degree according to the Lotgering's method for the (HKL) diffraction when X-ray diffraction is performed on the plane perpendicular to the orientation axis. The axis orientation degree of a powder compact where a specific crystal plane is almost completely axis-oriented, becomes nearly the same as the axis orientation degree measured of a powder compact where a specific crystal plane is almost completely plane-oriented.

The characteristics of the piezoelectric sensor using the crystal-oriented piezoelectric ceramic according to the present invention are described below.

The thermal stress which is generated when the piezoelectric sensor using the crystal-oriented piezoelectric ceramic undergoes temperature change, is described below.

The crystal-oriented piezoelectric ceramic has a thermal expansion coefficient of 3.0 ppm/° C. or more in the temperature range from −30° C. to 160° C. Therefore, the requirement (a) can be easily realized. As a result, in the piezoelectric sensor using the crystal-oriented piezoelectric ceramic, the difference in the thermal expansion coefficient from, for example, a holding member comprising a metal, a resin or the like having a thermal expansion coefficient more than 3.0 ppm/° C. can be decreased. In turn, the piezoelectric sensor using the crystal-oriented piezoelectric ceramic can be reduced in the thermal stress which is generated when the piezoelectric sensor undergoes temperature change, and fluctuation in the sensitivity due to temperature change or breakdown of the piezoelectric sensor due to thermal stress can be prevented.

The pyroelectric characteristic of the piezoelectric sensor using the crystal-oriented piezoelectric ceramic is described below.

The crystal-oriented piezoelectric ceramic has a pyroelectric coefficient of 400 μCm⁻²K⁻¹ or less in the temperature range from −30° C. to 160° C. Therefore, the requirement (b) can be easily realized. As a result, the generation of noise due to temperature change of the piezoelectric sensor can be prevented as described above. Furthermore, in the piezoelectric sensor using the crystal-oriented piezoelectric ceramic, as the voltage generated between terminals can be reduced as described above, the product can take a form that a short-circuit between terminals, by the use of a metal clipping jig or the like, is omitted or a resistor is not loaded between terminals.

The mechanical strength of the sensor using the crystal-oriented piezoelectric ceramic is described below.

The biaxial flexure breaking load of the crystal-oriented piezoelectric ceramic is larger than that of the PZT-type piezoelectric ceramic. Accordingly, the piezoelectric sensor using the crystal-oriented piezoelectric ceramic is excellent in the mechanical strength and can be hardly broken down.

The piezoelectric characteristics of the sensor using the crystal-oriented piezoelectric ceramic are described below.

In the crystal-oriented piezoelectric ceramic, the piezoelectric constant g₃₁ can be 0.006 Vm/N or more in the temperature range from −30° C. to 160° C. Furthermore, when the composition and process are appropriately selected, a piezoelectric constant g₃₁ of 0.007 Vm/N or more, even 0.008 Vm/N or more, still even 0.009 Vm/N or more, can be obtained. In addition, in the crystal-oriented piezoelectric ceramic, the fluctuation width of the piezoelectric constant g₃₁ can be ±15% or less by taking (maximum value−minimum value)/2 as the reference value. Furthermore, when the composition and process are appropriately selected, a fluctuation width of ±12% or less, even ±10% or less, still even ±8% or less, can be obtained.

Also, in the crystal-oriented piezoelectric ceramic, the piezoelectric constant d₃₁ can be 70 pC/N or more in the temperature range from −30° C. to 160° C. Furthermore, when the composition and process are appropriately selected, a piezoelectric constant d₃₁ of 80 pC/N or more, even 85 pC/N or more, and even 90 pC/N or more, can be obtained. In addition, in the crystal-oriented piezoelectric ceramic, the fluctuation width of the piezoelectric constant d₃₁ can be ±15% or less by taking (maximum value−minimum value)/2 as the reference value. Furthermore, when the composition and process are appropriately selected, a fluctuation width of ±12% or less, even ±10% or less, and even ±8% or less, can be obtained.

Therefore, the piezoelectric sensor of the present invention using the crystal-oriented piezoelectric ceramic according to the present invention can ensure that, irrespective of the circuit system to be connected, the circuit output voltage is increased and the fluctuation width of the circuit output voltage in the working temperature range is decreased.

### EXAMPLES

### Example 1

(1) Synthesis of NaNbO₃ Plate-Like Powder

A Bi₂O₃ powder, an Na₂CO₃ powder and an Nb₂O₅ powder were weighed to give a Bi_{2.5}Na_{3.5}Nb₅O₁₈ composition in terms of the stoichiometric ratio, and these powders were wet-mixed. Subsequently, NaCl was added as the flux in an amount of 50 wt %, and the resulting raw material was dry-mixed for 1 hour.

The obtained mixture was charged into a platinum crucible, heated at 850° C. for 1 hour and after the flux was completely melted, further heated at 1,100° C. for 2 hours, thereby synthesizing Bi_{2.5}Na_{3.5}Nb₅O₁₈. Here, the temperature rising rate was 200° C./hr and the temperature dropping was performed by furnace cooling. After cooling, the flux was removed from the reaction product by hot water washing to obtain a Bi_{2.5}Na_{3.5}Nb₅O₁₈ powder. The obtained Bi_{2.5}Na_{3.5}Nb₅O₁₈ powder was a plate-like powder with the developed plane being a {001} plane.

Thereafter, an Na₂CO₃ powder in an amount necessary for the synthesis of NaNbO₃ was added to the Bi_{2.5}Na_{3.5}Nb₅O₁₈ plate-like powder, and these powders were mixed and then heat-treated at a temperature of 950° C. for 8 hours in a platinum crucible by using NaCl as the flux.

In the obtained reaction product, Bi₂O₃ was contained in addition to the NaNbO₃ powder. Therefore, the reaction product after removing the flux therefrom was dipped in HNO₃ (1 N) to dissolve Bi₂O₃ produced as a surplus component. Subsequently, the NaNbO₃ powder was separated by filtering the resulting solution and then washed with ion-exchanged water at 80° C. The obtained NaNbO₃ powder was a plate-like powder having a particle diameter of 10 to 30 μm and an aspect ratio of approximately from 10 to 20, with the developed plane being a pseudo-cubic {100} plane.

(2) Production of Crystal-Oriented Ceramic Having {Li_{0.07}(K_{0.43}Na_{0.57})_{0.93}}{Nb_{0.84}Ta_{0.09}Sb_{0.07}}O₃ Composition

An Na₂CO₃ powder, a K₂CO₃ powder, an Li₂CO₃ powder, an Nb₂O₅ powder, a Ta₂O₅ powder and an Sb₂O₅ powder each having a purity of 99.99% or more were weighed to give a composition formulated by subtracting 0.05 mol of NaNbO₃ from 1 mol of the stoichiometric composition of {Li_{0.07}(K_{0.43}Na_{0.57})_{0.93}}{Nb_{0.84}Ta_{0.09}Sb_{0.07}}O₃, and these powders were wet-mixed for 20 hours by using an organic solvent as the medium and using Zr balls. The resulting mixed powder was then temporarily fired at 750° C. for 5 hours and further wet-ground for 20 hours by using an organic solvent as the medium and using Zr balls, whereby a temporarily fired powder having an average particle diameter of about 0.5 μm was obtained.

This temporarily fired powder and the plate-like NaNbO₃ powder prepared above were weighed at a ratio of temporarily fired powder: NaNbO₃=0.95 mol:0.05 mol to give an {Li_{0.07}(K_{0.48}Na_{0.57})_{0.93}}{Nb_{0.84}Ta_{0.09}Sb_{0.07}}O₃ composition, and wet-mixed for 20 hours by using an organic solvent as the medium and Zr balls to obtain a ground slurry. Subsequently, a binder (polyvinyl butyral) and a plasticizer (dibutyl phthalate) were added thereto, and the slurry was further mixed for 2 hours.

This slurry after mixing was shaped into a tape with a thickness of about 100 μm by using a tape molding apparatus, and these tapes were stacked, press-bonded and roll-pressed to obtain a 1.5 mm-thick plate-like powder compact. The obtained plate-like powder compact was then degreased in air under the conditions that the heating temperature was 600° C., the heating time was 5 hours, the temperature rising rate was 50° C./hr, and the cooling rate was furnace cooling. Furthermore, the plate-like powder compact after degreasing was subjected to a CIP treatment under a pressure of 300 MPa and then sintered in oxygen at 1,110° C. for 5 hours. In this way, a piezoelectric ceramic (crystal-oriented piezoelectric ceramic) was produced.

The obtained piezoelectric ceramic was measured on the sintering density and with respect to the plane parallel to the tape plane, the average orientation degree F(100) of the {100} plane according to the Lotgering's method was calculated by using the formula of Math. 1.

Subsequently, the obtained piezoelectric ceramic was ground, polished and machined to produce a piezoelectric ceramic as a disc-like sample having a thickness of 0.485 mm and a diameter of 8.5 mm, with the top and bottom planes being parallel to the tape plane. On the top and bottom-planes thereof, an Au electrode printing paste (ALP3057, produced by Sumitomo Metal Mining Co., Ltd.) was printed, dried and then baked at 850° C. for 10 minutes by using a mesh belt furnace to form a 0.01 mm-thick electrode on the piezoelectric ceramic. Furthermore, this disc-like sample was processed into a diameter of 8.5 mm by cylindrical grinding so as to remove the raised part of several micrometers inevitably formed in the outer periphery of the electrode at the printing of the Au electrode printing paste, and then a poling treatment was applied in the vertical direction to obtain a piezoelectric element (single plate) where an electrode was formed on the entire surface of the piezoelectric ceramic. The piezoelectric characteristics, i.e., piezoelectric constant (g₃₁), piezoelectric constant (d₃₁), electromechanical coupling factor (kp) and mechanical quality factor (Qm), and the dielectric characteristics, i.e., relative dielectric constant (∈₃₃t/∈₀) and dielectric loss (tan δ), of the obtained piezoelectric element were measured at room temperature (25° C.) by a resonance-antiresonance method.

Also, the first crystal phase transition temperature (Curie temperature) and the second crystal phase transition temperature were determined by measuring the temperature characteristic of the relative dielectric constant. Incidentally, in the case where the second crystal phase transition temperature is 0° C. or less, the fluctuation width of the relative dielectric constant on the temperature side higher than the second crystal phase transition temperature becomes very small. Therefore, when the peak position of the relative dielectric constant could not be specified, the temperature at which the relative dielectric constant line bends was used as the second crystal phase transition temperature.

The relative density of the crystal-oriented ceramic obtained in this Example was 95% or more. Also, the pseudo-cubic {100} plane was oriented in parallel to the tape plane, and the average orientation degree of the pseudo-cubic {100} plane according to the Lotgering's method reached up to 88.5%. Furthermore, the piezoelectric characteristics at room temperature (25° C.) were evaluated, as a result, the piezoelectric constant g₃₁ was 0.0094 Vm/N, the piezoelectric constant d₃₁ was 86.5 pm/V, the electromechanical coupling factor kp was 48.8%, and the mechanical quality factor Qm was 18.2. As for the dielectric characteristics, the relative dielectric constant ∈₃₃t/∈₀ was 1,042, and the dielectric loss tan δ was 6.4%. In addition, the first crystal phase transition temperature (Curie temperature) determined from the temperature characteristic of the relative dielectric constant was 282° C., and the second crystal phase transition temperature was −30° C. These results are shown in Table 1.

### Example 2

A crystal-oriented ceramic having an {Li_{0.07}(K_{0.45}Na_{0.55})_{0.93}}{Nb_{0.82}Ta_{0.10}Sb_{0.08}}O₃ composition was produced according to the same procedure as in Example 1 except that the firing temperature of the plate-like powder compact after degreasing was 1,105° C. The sintering density, average orientation degree and piezoelectric characteristics of the obtained crystal-oriented ceramic (piezoelectric ceramic) were evaluated under the same conditions as in Example 1. Also, the sintering density, average orientation degree and piezoelectric characteristics of the obtained crystal-oriented ceramic were evaluated under the same conditions as in Example 1.

The relative density of the crystal-oriented ceramic obtained in this Example was 95% or more. Also, the pseudo-cubic {100} plane was oriented in parallel to the tape plane, and the average orientation degree of the pseudo-cubic {100} plane according to the Lotgering's method reached up to 94.6%. Furthermore, the piezoelectric characteristics at room temperature (25° C.) were evaluated, as a result, the piezoelectric constant g₃₁ was 0.0093 Vm/N, the piezoelectric constant d₃₁ was 88.1 pm/V, the electromechanical coupling factor kp was 48.9%, and the mechanical quality factor Qm was 16.6. As for the dielectric characteristics, the relative dielectric constant ∈₃₃t/∈₀ was 1,071, and the dielectric loss tan δ was 4.7%. In addition, the first crystal phase transition temperature (Curie temperature) determined from the temperature characteristic of the relative dielectric constant was 256° C., and the second crystal phase transition temperature was −35° C. These results are shown in Table 1.

### Example 3

A crystal-oriented ceramic having an {Li_{0.065}(K_{0.45}Na_{0.55})_{0.935}}{Nb_{0.83}Ta_{0.09}Sb_{0.08}}O₃ composition was produced according to the same procedure as in Example 1 except that the firing temperature of the plate-like powder compact after degreasing was 1,105° C. The sintering density, average orientation degree and piezoelectric characteristics of the obtained crystal-oriented ceramic were evaluated under the same conditions as in Example 1.

The relative density of the crystal-oriented ceramic obtained in this Example was 95% or more. Also, the pseudo-cubic {100} plane was oriented in parallel to the tape plane, and the average orientation degree of the pseudo-cubic {100} plane according to the Lotgering's method reached up to 93.9%. Furthermore, the piezoelectric characteristics at room temperature (25° C.) were evaluated and, as a result, the piezoelectric constant g₃₁ was 0.0093 Vm/N, the piezoelectric constant d₃₁ was 95.2 pm/V, the electromechanical coupling factor kp was 50.4%, and the mechanical quality factor Qm was 15.9. The relative dielectric constant ∈₃₃t/∈₀ was 1,155, and the dielectric loss tan δ was 5.2%. In addition, the first crystal phase transition temperature (Curie temperature) determined from the temperature characteristic of the relative dielectric constant was 261° C., and the second crystal phase transition temperature was −12° C. These results are shown in Table 1.

### Example 4

In this Example, a crystal-oriented ceramic having the same composition as in Example 1 is produced according to a procedure different from that of Example 1.

A NaNbO₃ plate-like powder produced in Example 1, a non-plate-like NaNbO₃ powder, a KNbO₃ powder, a KTaO₃ powder, an LiSbO₃ powder and an NaSbO₃ powder were weighed to give an {Li_{0.07}(K_{0.43}Na_{0.57})_{0.93})}{Nb_{0.84}Ta_{0.09}Sb_{0.07}}O₃ composition, and these powders were wet-mixed for 20 hours by using an organic solvent as the medium.

Subsequently, a binder (polyvinyl butyral) and a plasticizer (dibutyl phthalate) were added thereto, and the resulting slurry was further mixed for 2 hours.

Incidentally, the blending amount of the NaNbO₃ plate-like powder was set so that 5 at % of the A-site element of the first KNN-type solid solution synthesized from starting materials could be supplied from the NaNbO₃ plate-like powder. Also, the non-plate-like NaNbO₃ powder, KNbO₃ powder, KTaO₃ powder, LiSbO₃ powder and NaSbO₃ powder were prepared by a solid phase process of heating a mixture containing a K₂CO₃ powder, an Na₂CO₃ powder, an Nb₂O₅ powder, a Ta₂O₅ powder and/or an Sb₂O₅ powder each in a predetermined amount and each having a purity of 99.9%, at 750° C. for 5 hours, and pulverizing the reactant in a ball mill.

The slurry after mixing was shaped into a tape with a thickness of 100 μm by using a doctor blade device, and these tapes were stacked, press-bonded and roll-pressed to obtain a 1.5 mm-thick plate-like powder compact. The obtained plate-like powder compact was then degreased in air under the conditions that the heating temperature was 600° C., the heating time was 5 hours, the temperature rising rate was 50° C./hr, and the cooling rate was furnace cooling. Furthermore, the plate-like powder compact after degreasing was subjected to a CIP treatment under a pressure of 300 MPa and then to a hot press sintering of applying a pressure of 35 kg/cm² (3.42 MPa) during heating in oxygen under the conditions that the firing temperature was 1,130° C., the heating time was 5 hours, and the temperature rising or dropping rate was 200° C./hr. In this way, a piezoelectric ceramic (crystal-oriented piezoelectric ceramic) was produced.

The crystal-oriented piezoelectric ceramic obtained in this Example was sufficiently densified, and the bulk density was 4.78 g/cm³. Also, the pseudo-cubic {100} plane was oriented in parallel to the tape plane, and the average orientation degree of the pseudo-cubic {100} plane according to the Lotgering's method reached up to 96%.

Furthermore, the piezoelectric characteristics at room temperature (25° C.) were evaluated, as a result, the piezoelectric constant g₃₁ was 0.0101 Vm/N, the piezoelectric constant d₃₁ was 96.5 pm/V, the electromechanical coupling factor kp was 51.9%, and the mechanical quality factor Qm was 15.2. The relative dielectric constant ∈₃₃t/∈₀ was 1,079, and the dielectric loss tan δ was 4.7%. In addition, the first crystal phase transition temperature (Curie temperature) determined from the temperature characteristic of the relative dielectric constant was 279° C., and the second crystal phase transition temperature was −28° C. These results are shown in Table 1.

### Example 5

In this Example, a piezoelectric ceramic (crystal-oriented piezoelectric ceramic) having a composition formulated by externally adding 0.0005 mol of Mn to 1 mol of {Li_{0.065}(K_{0.45}Na_{0.55})_{0.935}}{Nb_{0.83}Ta_{0.09}Sb_{0.08}}O₃ which is the composition in Example 3, is produced.

A Na₂CO₃ powder, a K₂CO₃ powder, an Li₂CO₃ powder, an Nb₂O₅ powder, a Ta₂O₅ powder, an Sb₂O₅ powder and an MnO₂ powder each having a purity of 99.99% or more were weighed to give a composition formulated by subtracting 0.05 mol of NaNbO₃ from a composition comprising 1 mol of {Li_{0.07}(K_{0.43}Na_{0.57})_{0.93}}{Nb_{0.84}Ta_{0.09}Sb_{0.07}}O₃ and 0.0005 mol of Mn, and these powders were wet-mixed for 20 hours by using an organic solvent as the medium and using Zr balls. The resulting mixed powder was then temporarily fired at 750° C. for 5 hours and further wet-ground for 20 hours by using an organic solvent as the medium and using Zr balls, whereby a temporarily fired powder having an average particle diameter of about 0.5 μm was obtained.

The subsequent procedure was performed in the same manner as in Example 1 except that the firing temperature of the plate-like powder compact after degreasing was 1,105° C. In this way, a crystal-oriented ceramic having a composition comprising 1 mol of {Li_{0.065}(K_{0.45}Na_{0.55})_{0.935}}{Nb_{0.83}Ta_{0.09}Sb_{0.08}}O₃ and 0.0005 mol of Mn was produced.

The sintering density, average orientation degree and piezoelectric characteristics of the obtained crystal-oriented ceramic were evaluated under the same conditions as in Example 1.

The relative density of the crystal-oriented ceramic obtained in this Example was 95% or more. Also, the pseudo-cubic {100} plane was oriented in parallel to the tape plane, and the average orientation degree of the pseudo-cubic {100} plane according to the Lotgering's method reached up to 89.6%.

Furthermore, the piezoelectric characteristics at room temperature (25° C.) were evaluated and, as a result, the piezoelectric constant g₃₁ was 0.0097 Vm/N, the piezoelectric constant d₃₁ was 99.1 pm/V, the electromechanical coupling factor kp was 52.0%, and the mechanical quality factor Qm was 20.3. The relative dielectric constant ∈₃₃t/∈₀ was 1,159, and the dielectric loss tan δ was 2.7%. It is seen from these results that the addition of Mn has an effect on the elevation of Qm and the reduction of tan δ.

In addition, the first crystal phase transition temperature (Curie temperature) determined from the temperature characteristic of the relative dielectric constant was 2,263° C., and the second crystal phase transition temperature was −15° C. These results are shown in Table 1.

### Comparative Example 1

In Comparative Example 1, a piezoelectric ceramic comprising a tetragonal PZT material having a characteristic (semihard) intermediate between soft type and hard type, which is suitable for a multilayer actuator for a fuel injection valve of an automobile, was produced. Here, the soft type means a material having Qm of 100 or less, and the hard type is a material having Qm of 1,000 or more.

In the production of the piezoelectric ceramic of this Example, a PbO power, a ZrO₂ powder, a TiO₂ powder, an SrCO₃ powder, a Y₂O₃ powder, an Nb₂O₅ powder and an Mn₂O₃ powder were weighed to give a (Pb_{0.92}Sr_{0.09}){(Zr_{0.543}Ti_{0.457})_{0.985}(Y_{0.5}Nb_{0.5})_{0.01}Mn_{0.05}}O₃ composition, and these powders were wet-mixed by using water as the medium and using Zr balls. The resulting mixed powder was then temporarily fired at 790° C. for 7 hours and further wet-ground by using an organic solvent as the medium and using Zr balls, whereby a temporarily fired powder having an average particle diameter of about 0.7 μm was obtained as a slurry.

Subsequently, a binder (polyvinyl butyral) and a plasticizer (dibutyl phthalate) were added thereto, and the slurry was then mixed for 20 hours by using Zr balls.

This slurry after mixing was shaped into a tape with a thickness of about 100 μm by using a tape molding apparatus, and these tapes were stacked and thermally press-bonded to obtain a 1.2 mm-thick plate-like powder compact. The obtained plate-like powder compact was then degreased in air. Furthermore, the plate-like powder compact after degreasing was placed on an MgO plate in an alumina sagger and sintered in air at 1,170° C. for 2 hours.

The subsequent procedure was performed in the same manner as in Example 1 except for print-baking an Ag paste as the electrode material.

The relative density of the piezoelectric ceramic of this Comparative Example was 95% or more. Also, the piezoelectric characteristics at room temperature (25° C.) were evaluated, as a result, the piezoelectric constant g₃₁ was 0.01057 Vm/N, the piezoelectric constant d₃₁ was 158.0 pm/V, the electromechanical coupling factor kp was 60.2%, and the mechanical quality factor Qm was 540. The relative dielectric constant ∈₃₃t/∈₀ was 1,701, and the dielectric loss tan δ was 0.2%. These results are shown in Table 1.

### Comparative Example 2

In Comparative Example 2, a piezoelectric ceramic comprising a soft-type rhombohedral PZT material suitable for a multilayer actuator for the positioning of a semiconductor production apparatus or the like, and less subject to an environmental temperature change, was produced.

In the production of the piezoelectric ceramic of this Example, a PbO power, a ZrO₂ powder, a TiO₂ powder, an SrCO₃ powder, a Y₂O₃ powder and an Nb₂O₅ powder were weighed to give a (Pb_{0.895}Sr_{0.115}){(Zr_{0.57}Ti_{0.43})_{0.978}(Y_{0.5}Nb_{0.5})_{0.01}Nb_{0.012}}O₃ composition, and these powders were wet-mixed for 20 hours by using water as the medium and using Zr balls. The resulting mixed powder was then temporarily fired at 875° C. for 5 hours and further wet-ground by using water as the medium and using Zr balls.

Subsequently, a binder (polyvinyl butyral) and a plasticizer (dibutyl phthalate) were added thereto to have a concentration of 1 wt % based on the temporarily fired powder material, and the slurry was then dried by a spray drier and granulated.

From this product, a φ15 powder compact having a thickness of 2 mm was obtained through dry press molding using a mold. Thereafter, the obtained disc-like powder compact was degreased in air. Furthermore, the plate-like powder compact after degreasing was subjected to a CIP treatment under a pressure of 200 MPa, then placed on an MgO plate in an alumina sagger and sintered in air at 1,260° C. for 2 hours. The subsequent procedure was performed in the same manner as in Comparative Example 1.

The relative density of the piezoelectric ceramic of this Comparative Example was 95% or more. Also, the piezoelectric characteristics at room temperature (25° C.) were evaluated, as a result, the piezoelectric constant g₃₁ was 0.0124 Vm/N, the piezoelectric constant d₃₁ was 212.7 pm/V, the electromechanical coupling factor kp was 67.3%, and the mechanical quality factor Qm was 47.5. The relative dielectric constant ∈₃₃t/∈₀ was 1,943, and the dielectric loss tan δ was 2.1%. These results are shown in Table 1.

### Comparative Example 3

In Comparative Example 3, a piezoelectric ceramic comprising a soft-type tetragonal PZT material suitable for a knock sensor of an automobile was produced.

In the production of the piezoelectric ceramic of this Example, a PbO power, a ZrO₂ powder, a TiO₂ powder, an SrTiO₃ powder and an Sb₂O₃ powder were weighed to give a (Pb_{0.95}Sr_{0.05}){(Zr_{0.53}Ti_{0.47})_{0.978}Sb_{0.022}}O₃ composition, and these powders were wet-mixed for 20 hours by using water as the medium and using Zr balls. The resulting mixed powder was then temporarily fired at 825° C. for 5 hours and further wet-ground by using water as the medium and using Zr balls.

The subsequent procedure was performed in the same manner as in Comparative Example 2 except that the sintering temperature was 1,230° C.

The relative density of the piezoelectric ceramic of this Comparative Example was 95% or more. Also, the piezoelectric characteristics at room temperature (25° C.) were evaluated, as a result, the piezoelectric constant g₃₁ was 0.0100 Vm/N, the piezoelectric constant d₃₁ was 203.4 pm/V, the electromechanical coupling factor kp was 62.0%, and the mechanical quality factor Qm was 55.8. The relative dielectric constant ∈₃₃t/∈₀ was 2,308, and the dielectric loss tan δ was 1.4%. These results are shown in Table 1.

### Comparative Example 4

In Comparative Example 4, a piezoelectric ceramic comprising a semihard-type tetragonal PZT material suitable for a high-output ultrasonic motor was produced.

In the production of the piezoelectric ceramic of this Example, a PbO power, a ZrO₂ powder, a TiO₂ powder, an SrCO₃ powder, an Sb₂O₃ powder and an MnCO₃ powder were weighed to give a (Pb_{0.965}Sr_{0.05}){(Zr_{0.5}Ti_{0.5})_{0.96}Sb_{0.03}Mn_{0.01}}O₃ composition, and these powders were wet-mixed by using water as the medium and using Zr balls. The resulting mixed powder was then temporarily fired at 875° C. for 5 hours and further wet-ground by using water as the medium and using Zr balls.

The subsequent procedure was performed in the same manner as in Comparative Example 2 except that the sintering temperature was 1,230° C.

The relative density of the piezoelectric ceramic of this Comparative Example was 95% or more. Also, the piezoelectric characteristics at room temperature (25° C.) were evaluated, as a result, the piezoelectric constant g₃₁ was 0.0100 Vm/N, the piezoelectric constant d₃₁ was 136.9 pm/V, the electromechanical coupling factor kp was 57.9%, and the mechanical quality factor Qm was 850. The relative dielectric constant ∈₃₃t/∈₀ was 1,514, and the dielectric loss tan δ was 0.2%. These results are shown in Table 1.

### Comparative Example 5

In Comparative Example 5, a piezoelectric ceramic comprising a hard-type tetragonal PZT material suitable for a high-sensitivity angular velocity sensor is produced.

In the production of the piezoelectric ceramic of this Example, a PbO power, a ZrO₂ powder, a TiO₂ powder, a ZnO powder, an MnCO₃ powder and an Nb₂O₅ powder were weighed to give a Pb{(Zr_{0.5}Ti_{0.5})_{0.98}(Zn_{0.33}Nb_{0.67})_{0.01}Mn_{0.01}}O₃ composition, and these powders were wet-mixed by using water as the medium and using Zr balls. The resulting mixed powder was then temporarily fired at 800° C. for 5 hours and further wet-ground by using water as the medium and using Zr balls.

The subsequent procedure was performed in the same manner as in Comparative Example 2 except that the sintering temperature was 1,200° C.

The relative density of the piezoelectric ceramic of this Comparative Example was 95% or more. Also, the piezoelectric characteristics at room temperature (25° C.) were evaluated and, as a result, the piezoelectric constant g₃₁ was 0.0110 Vm/N, the piezoelectric constant d₃₁ was 103.6 pm/V, the electromechanical coupling factor kp was 54.1%, and the mechanical quality factor Qm was 1,230. The relative dielectric constant ∈₃₃t/∈₀ was 1,061, and the dielectric loss tan δ was 0.3%. These results are shown in Table 1.

### Example 6

In this Example, the fluctuation of the piezoelectric constant in a fixed temperature range was evaluated.

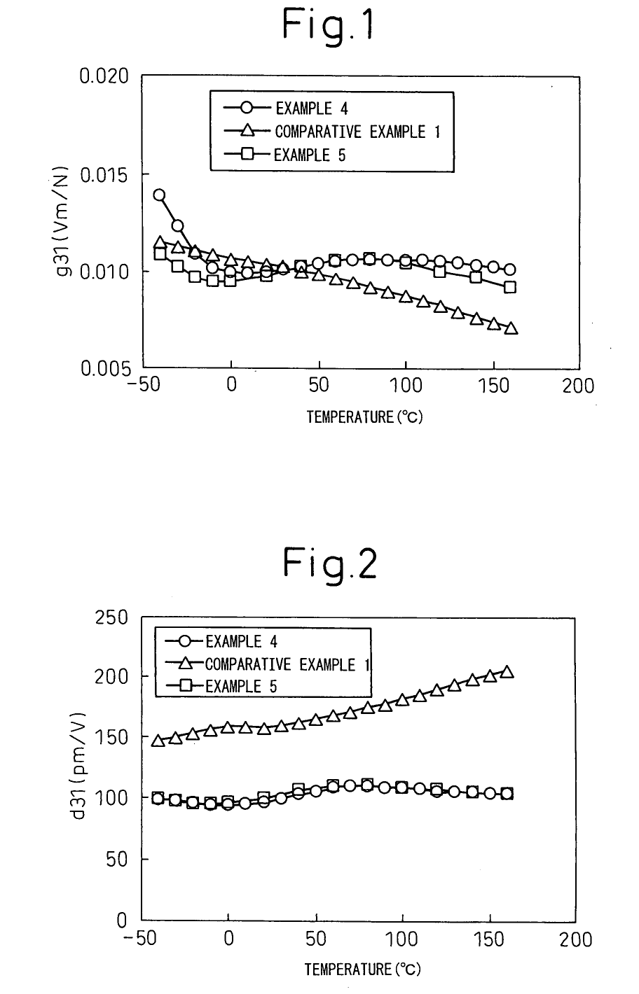

The temperature characteristics of the piezoelectric constant g₃₁ and piezoelectric constant d₃₁ in a temperature range from −40° C. to 160° C. of each of the piezoelectric elements produced in Examples 4 and 5 and Comparative Example 1 are shown in FIGS. 1 and 2, respectively.

First, the fluctuation width of the piezoelectric constant g₃₁ is described. The fluctuation width as referred to herein is a fluctuation width by taking (maximum value−minimum value) in each temperature range from −30° C. to 80° C. or from −30° C. to 160° C. as the reference value.

As seen from FIG. 1, the fluctuation width of the piezoelectric constant g₃₁ in the temperature range from −30° C. to 160° C. was 10.9% in the piezoelectric element of Example 4, 6.1% in the piezoelectric element of Example 5, and 10.2% in Comparative Example 1.

Also, the fluctuation width in the temperature range from −30° C. to 160° C. was 10.9% in the piezoelectric element of Example 4, 6.1% in the piezoelectric element of Example 5, and 22.6% in Comparative Example 1.

Accordingly, it can be understood that the piezoelectric elements of Examples 4 and 5 have a fluctuation of the piezoelectric constant g₃₁ smaller than that of Comparative Example 1.

Next, the fluctuation of the piezoelectric constant d₃₁ is described. The fluctuation referred to here is a fluctuation taking (maximum value−minimum value) in each temperature range from −30° C. to 80° C. or from −30° C. to 160° C. as the reference value.

As seen from FIG. 2, the fluctuation of the piezoelectric constant d₃₁ in the temperature range from −30° C. to 160° C. was 7.8% in the piezoelectric element of Example 4, 7.3% in the piezoelectric element of Example 5, and 7.8% in Comparative Example 1.

Also, the fluctuation in the temperature range from −30° C. to 160° C. was 7.8% in the piezoelectric element of Example 4, 7.3% in the piezoelectric element of Example 5, and 15.8% in Comparative Example 1.

Accordingly, it is understood that the piezoelectric elements of Examples 4 and 5 have a fluctuation of the piezoelectric constant d₃₁ smaller than that of Comparative Example 1.

### (Example 7) Temperature Characteristic of Tan δ

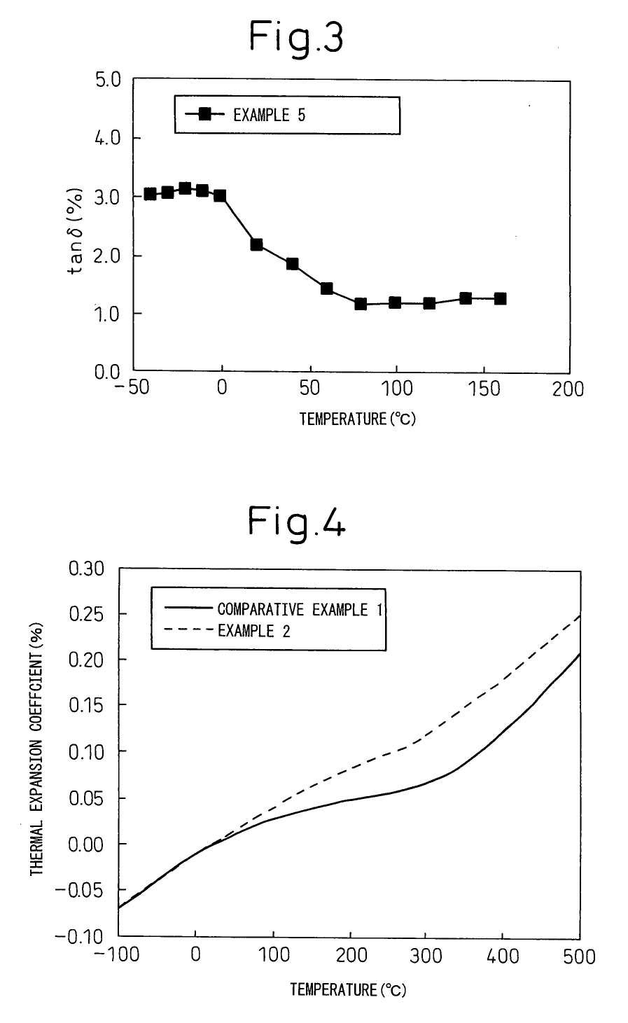

The temperature characteristic of the dielectric loss (tan δ) of the piezoelectric element produced in Example 5 was measured and the results are shown in FIG. 3.

As seen from FIG. 3, the dielectric loss (tan δ) of the piezoelectric element of Example 5 is high at a temperature of −30° C. to 0° C. in the temperature range from −30° C. to 160° C., and the value thereof is about 3%, which is not so different from the dielectric loss at room temperature (25° C.) of the piezoelectric element produced in Comparative Example 2, that is, 2.1%.

Accordingly, it can be understood that the piezoelectric sensor using the crystal-oriented piezoelectric ceramic (Example 5) of the present invention generates less noise which gives rise to less dielectric loss.

### (Example 8) Measurement of Thermal Expansion Coefficient

The linear thermal expansion coefficient and thermal expansion factor of each of the sintered bodies (piezoelectric ceramics) obtained in Example 2 and Comparative Example 1 were measured and the results are shown in Table 2. Also, FIG. 4 shows the temperature characteristic of the linear thermal expansion coefficient based on the reference temperature of 25° C.

In the measurement of the linear thermal expansion coefficient, the piezoelectric ceramics produced in Example 2 and Example 1 each was processed by grinding into a dimension of 5 mm (width)×1.5 mm (thickness)×10 mm (length) and used as a sample for the measurement of linear thermal expansion coefficient.

The measurement of the linear thermal expansion coefficient was performed by a TMA method using a thermal mechanical analyzer TMA-50 manufactured by Shimadzu Corp. under the conditions that the measurement temperature range was from −100° C. to 500° C., the temperature rising rate was 2° C./min, and the measurement atmosphere was air.

The linear thermal expansion coefficient is defined as the length change ratio ΔL/L₀ from the sample length L₀ at the reference temperature (25° C.) and its variation ΔL by temperature. Based on the temperature curve of this linear thermal expansion coefficient (ΔL/L₀), the linear thermal expansion factor β was determined according to formula A4. Here, β was calculated by the central difference method with dT=20° C. Incidentally, β corresponds to the temperature derivative value of the ΔL/L₀ temperature curve.
β=(1/L₀)×(dL/dT) (A4)
wherein L₀ is the sample length at the reference temperature (25° C.), dT is the temperature difference (20° C.), and dL is the expansion length at the temperature difference dT.

As shown in Table 2 and FIG. 4, the thermal expansion factor of Example 1 exceeded 4 ppm/° C. in the temperature range from −30° C. to 160° C., whereas the thermal expansion factor of Comparative Example 1 was less than 3 ppm/° C. in the temperature range from 100° C. to 160° C.

From this, it can be understood that, when the crystal-oriented piezoelectric ceramic (Example 2) of the present invention is used, a piezoelectric sensor generating less thermal stress between the piezoelectric ceramic, and a metal or resin having a thermal expansion factor larger than that of the piezoelectric ceramic, can be obtained.

In the same manner as in these Example 2 and Comparative Example 2, the linear thermal expansion coefficient was measured for the piezoelectric ceramics of Example 1, Examples 3 to 5 and Comparative Examples 2 to 5. The thermal expansion coefficient of Example 1 and Examples 3 to 5 exceeded 4 ppm/° C. in the temperature range from −30° C. to 160° C. similarly to Example 2, whereas the thermal expansion factor of Comparative Examples 2 to 5 was less than 3 ppm/° C. in the temperature range from 100° C. to 160° C. similarly to Comparative Example 1.

The average thermal expansion factor in the range from −30° C. to 160° C. (the value obtained by subtracting the thermal expansion coefficient at −30° C. from the thermal expansion coefficient at 160° C., and dividing the obtained value by 190° C. which is the temperature difference) was 5.3 ppm/° C. in Example 1, 5.1 ppm/° C. in Example 2, 5.0 ppm/° C. in Example 3, 5.3 ppm/° C. in Example 4, and 5.4 ppm/° C. in Example 5, thus exceeding 4 ppm/° C. in all samples. On the other hand, this value was 3.7 ppm/° C. in Comparative Example 1, 3.6 ppm/° C. in Comparative Example 2, 3.4 ppm/° C. in Comparative Example 3, 3.5 ppm/° C. in Comparative Example 4, and 3.8 ppm/° C. in Comparative Example 5, thus being less than 4 ppm/° C. in all samples. That is, it is found that also with respect to the parameter of average thermal expansion factor in the range from −30° C. to 160° C., the thermal expansion factor of the crystal-oriented piezoelectric ceramics of Examples 1 to 5 is larger than that in the samples of Comparative Examples.

### (Example 9) Measurement of Pyroelectric Coefficient

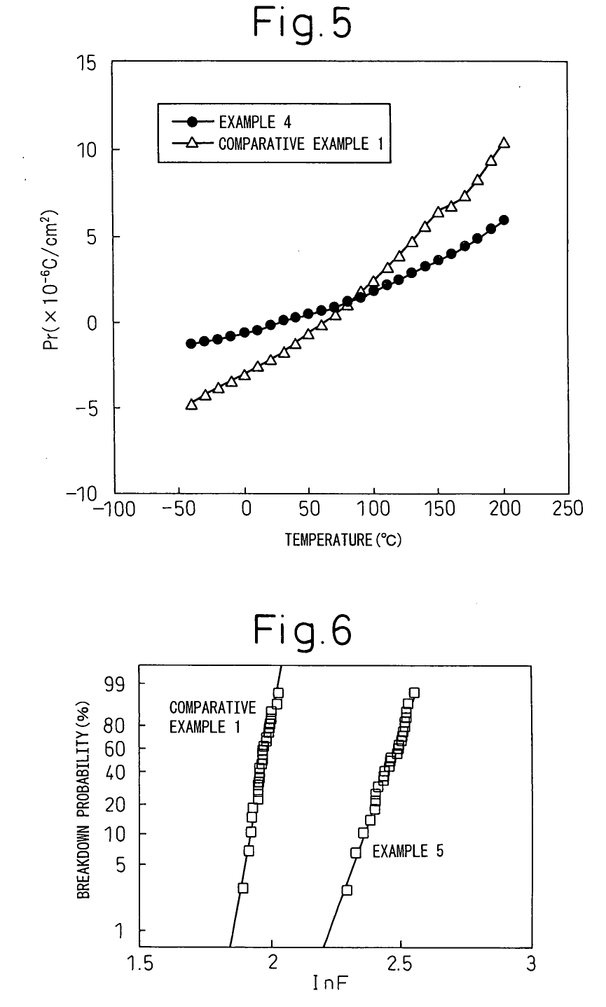

The temperature characteristic of the variation in the polarized amount Pr of each of the single-plate piezoelectric elements obtained in Example 4 and Comparative Example 1 was measured and the results are shown in FIG. 5.

In the measurement of the temperature characteristic of the polarized amount Pr, the piezoelectric elements obtained in Example 4 and Comparative Example 3 each itself was used as the same for measurement. The measurement was performed by the pyroelectric current method in the measurement temperature range from −40° C. to 200° C.

That is, the piezoelectric element was placed in a constant-temperature bath, and the temperature was lowered at a rate of 2° C./min from 25° C. to −40° C. and then elevated at a rate of 2° C./min from −40° C. to 200° C. At this time, the current flowing out from the electrodes on the top and bottom surfaces of the piezoelectric element was measured by a microammeter at intervals of about 30 seconds. Also, the temperature and the exact time at the measurement were simultaneously measured, and the variation ΔP [C/cm²] of the polarized amount and the temperature variation ΔT in the measurement time interval were determined according to the following formulae.
ΔP={(I₁+I₂)/2}×(t₁−t₂)/S
ΔT=T₁−T₂
wherein ΔP is the variation [μC/cm²) of the polarized amount, (t₁−t₂) is the measurement time interval [s], I₁ is the current [A] at the time t₁, T₁ is the temperature [° C.] at the time t₁, I₂ is the current [A] at t₂, T₂ is the temperature [° C.] at the time t₂, and S is the area [cm²] of the electrode on one side of the piezoelectric element. From the values obtained, the pyroelectric coefficient at temperature=(T₁+T₂)/2 was calculated according to pyroelectric coefficient=ΔP/ΔT, and the pyroelectric coefficient was determined as the absolute value.

The pyroelectric coefficient (=temperature coefficient of polarized amount Pr) of the single plate of Example 4 in the temperature range from −30° C. to 160° C. was 271 μCm⁻²K⁻¹.

On the other hand, the pyroelectric coefficient of the single plate of Comparative Example 1 was 581 μCm⁻²K⁻¹ and more than 2 times that of Example 4.

Accordingly, it can be understood that, when the crystal-oriented piezoelectric ceramic (Example 4) of the present invention is used, a sensor reduced in the terminal voltage which is generated due to environmental temperature change can be obtained.

In the same manner as in these Example 4 and Comparative Example 1, the pyroelectric coefficient in the temperature range from −30° C. to 160° C. was measured for the single plates of Examples 1 to 3, Example 5 and Comparative Examples 2 to 5 and found to be 280 μCm⁻²K⁻¹ in Example 1, 255 μCm⁻²K⁻¹ in Example 2, 230 μCm⁻²K⁻¹ in Example 3, 185 μCm⁻²K⁻¹ in Example 5, 605 μCm⁻²K⁻¹ in Comparative Example 2, 577 μCm⁻²K⁻¹ in Comparative Example 3, 546 μCm⁻²K⁻¹ in Comparative Example 4 and 560 μCm⁻²K⁻¹ in Comparative Example 5. That is, the pyroelectric coefficient of the crystal-oriented piezoelectric ceramics of Examples 1 to 5 was found to be smaller than that in the samples of Comparative Examples.

### (Example 10) Difference of Breaking Load

The breaking load of each of the sintered bodies (piezoelectric ceramics) obtained in Example 5 and Comparative Example 1 was measured, and the Weibull-plotted results are shown in FIG. 6.

In FIG. 6, the abscissa shows the natural logarithm of the braking load F [N], and the ordinate shows the breakdown probability (%).

In the measurement of the breaking load, the piezoelectric ceramics produced in Example 5 and Example 1 each was processed by grinding into a shape of 0.4 mm (thickness)×7 mm ( ) with four corners being chamfered in C1 mm, and used as the sample for measurement.

The breaking load was measured by a biaxial flexure test method (ball-on-ring method) using autograph, in which the ring was an SC211-made ring having an outer diameter of 6 mm and an inner diameter of 4 mm, the ball was a ZrO₂-made ball having a diameter of 2 mm, and the ring and the ball both were mirror-polished. The loading rate was set to 0.5 mm/min, and the number of samples was N=26 for Example 5 and N=25 for Comparative Example 1.

The breaking load F of Example 5 was 11.7 N on average (maximum: 12.9 N, minimum: 9.9 N), and the Weibull modulus was m=17.7. On the other hand, the breaking load of the sample in Comparative Example 1 was 7.2 N on average (maximum: 7.6 N, minimum: 6.7 N), and the Weibull modulus was m=34.8. Thus, the breaking load of Example was found to be more than two times that of Comparative Example.

Accordingly, it is understood that when the crystal-oriented piezoelectric ceramic (Example 5) of the present invention is used, a piezoelectric sensor less breakable by stress resulting from vibration during assembly or actual use can be obtained.

TABLE 1

| | Average | | | | | | | First Crystal | Second Crystal |
|---|---|---|---|---|---|---|---|---|---|
| | Orientation | tan δ | ε₃₃t/ε₀ | Qm | kp | g₃₁ | d₃₁ | Phase Transition | Phase Transition |
| Example No. | Degree [%] | [%] | [−] | [−] | [%] | [Vm/N] | [pm/V] | Temperature [° C.] | Temperature [° C.] |
| Example 1 | 88.5 | 6.4 | 1042 | 18.2 | 48.8 | 0.0094 | 86.5 | 282 | −30 |
| Example 2 | 94.5 | 4.7 | 1071 | 16.6 | 48.9 | 0.0093 | 88.1 | 256 | −35 |
| Example 3 | 93.9 | 5.2 | 1155 | 15.9 | 50.4 | 0.0093 | 95.2 | 261 | −12 |
| Example 4 | 96.0 | 4.7 | 1079 | 15.2 | 51.9 | 0.0101 | 96.5 | 279 | −28 |
| Example 5 | 89.6 | 2.7 | 1159 | 20.3 | 52.0 | 0.0097 | 99.1 | 263 | −15 |
| Comparative | — | 0.2 | 1701 | 540 | 60.2 | 0.0105 | 158.0 | — | — |
| Example 1 | | | | | | | | | |
| Comparative | — | 2.1 | 1943 | 47.5 | 67.3 | 0.0124 | 212.7 | — | — |
| Example 2 | | | | | | | | | |
| Comparative | — | 1.4 | 2308 | 55.8 | 62.0 | 0.0100 | 203.4 | — | — |
| example 3 | | | | | | | | | |
| Comparative | — | 0.2 | 1545 | 850 | 57.9 | 0.0100 | 136.9 | — | — |
| Example 4 | | | | | | | | | |
| Comparative | — | 0.2 | 1061 | 1230 | 54.1 | 0.0110 | 103.6 | — | — |
| Example 5 | | | | | | | | | |

TABLE 2

| | | Linear Thermal | |
|---|---|---|---|
| | | Expansion | Thermal Expansion |
| | Temperature | Coefficient: ΔL/L₀ | Factor: β |
| | [° C.] | [%] | [ppm/° C.] |
| Example 2 | −40 | −0.036 | 5.5 |
| | −30 | −0.030 | 5.8 |
| | 0 | −0.012 | 5.3 |
| | 20 | −0.002 | 4.7 |
| | 50 | 0.014 | 5.3 |
| | 80 | 0.029 | 5.2 |
| | 100 | 0.040 | 5.0 |
| | 120 | 0.049 | 4.8 |
| | 140 | 0.059 | 4.6 |
| | 160 | 0.068 | 4.1 |
| | 180 | 0.076 | 4.1 |
| | 200 | 0.083 | 3.6 |
| Comparative | −40 | −0.035 | 5.7 |
| Example 1 | −30 | −0.029 | 5.7 |
| | 0 | −0.011 | 5.6 |
| | 20 | −0.002 | 4.3 |
| | 50 | 0.011 | 3.9 |
| | 80 | 0.022 | 3.1 |
| | 100 | 0.027 | 2.7 |
| | 120 | 0.033 | 2.5 |
| | 140 | 0.037 | 2.2 |
| | 160 | 0.041 | 1.9 |
| | 180 | 0.045 | 1.7 |
| | 200 | 0.048 | 1.6 |

### Example 11

In this Example, a piezoelectric sensor using a piezoelectric ceramic comprising a crystal-oriented ceramic having the same composition as in Example 5 is produced.

The piezoelectric sensor of this Example is a knock sensor which is fixed to an automobile engine by a fastener such as bolt and is used for detecting abnormal combustion of the engine.

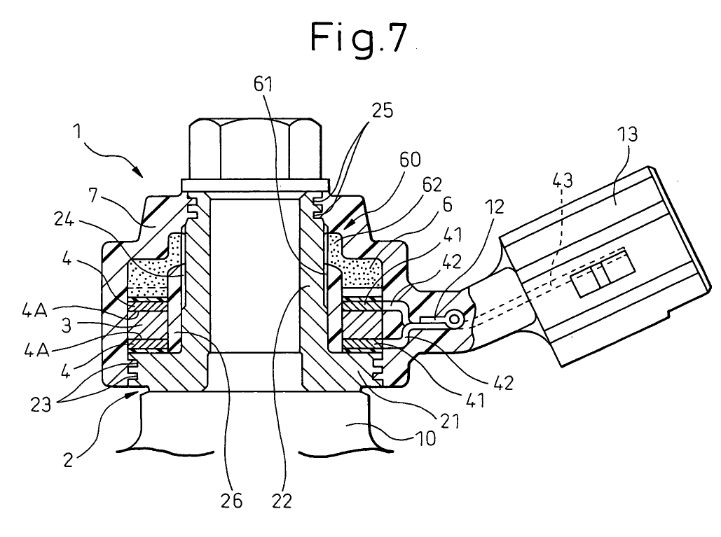

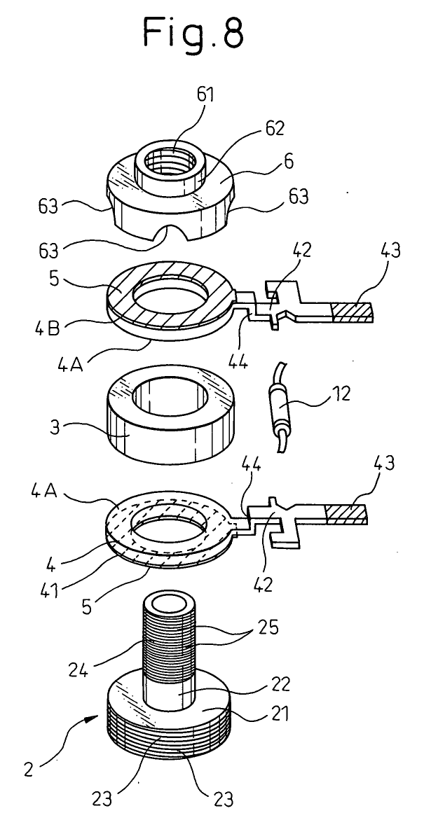

As shown in FIGS. 7 and 8, the piezoelectric sensor 1 of this Example comprises a tubular shaft made of a metal such as iron, with one end (bottom end of FIG. 7) working out to a pressure welding surface 11 to a cylinder block 10 of an internal combustion engine. The tubular shaft 2 comprises a collar part 21 provided at one end and a cylinder part 22. Two circumferential grooves 23 are provided in the outer periphery of the collar part 21. In the cylinder part 22, an outer screw 24 is threaded in the middle part, and two circumferential grooves 25 are formed at the other end (top end in the Figure) part.

A piezoelectric element 3 having a rectangular toric cross-section is concentrically arranged in the outer periphery of the cylinder part 22, and a brass electrode plate 4 is superposed on both surfaces in the axial direction of the piezoelectric element 3. The electrode plate 4 comprises an electrode part 41 having a nearly flushing shape and giving a toric plate appearance, a lead part 42 extending from the electrode part 41, and a gold-plated part 43 provided on a part of the lead part 42, and a hooked bend part 44 is provided in the lead part 42.

The piezoelectric element 3 and the electrode plate 4 are disposed concentrically with the cylinder part 22 via a circular gap 26 for the insulation. The piezoelectric element 3 side (inner side) surface 4A of the electrode part 41 serves as a pressure welding surface to the piezoelectric element 3, and an insulating layer 5 is provided on the opposite side (outer side) surface 4B from the piezoelectric element 3. On the other end side (top side in the Figure) of the cylinder part 22, a toric weight 6, flush with the electrode plate 4, is disposed and superposed.

In this Example, a diameter-reduced part 62 having an inner screw 61 is provided in the extended manner on the other end side of the weight 6 and screwed together with the outer screw 24. The collar part 21, the inner screw 61 and the outer screw 24 constitute a holding mechanism 60 for pressurizing and thereby concentrically holding the piezoelectric element 3 and the paired electrode plates 4 under a predetermined pressure. The electrode plates 4 are electrically connected through a resistor 12 fixed to the lead parts 42 by electric resistance welding.

On the joining surface of the weight 6 to the electrode plate 4, nearly semicircular grooves 63 are provided in a cross shape to allow for communication of the annular gap 26 with the outside. Also, a connector 13 is connected to the distal end of the lead part 42. In this state, a cover material 7 is formed by the mold forming of a resin to form insulation and waterproof covering for the outer peripheries of the weight 6, piezoelectric element 3 and electrode plates 4. The resin for the mold forming is filled also inside the annular gap through the grooves 63.

As for the holding mechanism, the diameter-reduced part having an inner screw may be a nut independent of the weight. Other than the combination of an inner screw and an outer screw, a washer may be engaged into a washer groove formed on the other end side of the cylinder part and an annular leaf spring may be interposed between the washer and the weight. In place of the washer, a clamp may be fitted into the other end part of the cylinder part, or the tope end of the annular leaf spring may be pressed by a nut.

The piezoelectric sensor 1 of this Example is assembled as follows.

First, a piezoelectric element 3 was produced. That is, a tape-shaped powder compact having a thickness of about 100 μm was produced by the same procedure as in Example 5, and this powder compact was cut into a dimension of 40×40 mm. Subsequently, 45 sheets of the powder compact in this dimension were stacked and press-bonded to produce a press-bonded stacked body. The center part of the press-bonded stacked body was bored by a drill to obtain a plate-like powder compact having a hole of φ10 mm in the center part of a powder compact of 40 mm in height, 40 mm in width and 4 mm in thickness.

The obtained plate-like powder compact was degreased in air. The degreasing was performed under the temperature conditions that the heating temperature was 600° C., the heating time was 5 hours, the temperature rising rate was 50° C./hr, and the cooling rate was furnace cooling. Thereafter, the plate-like powder compact after degreasing was heated in oxygen at 1,105° C. for 5 hours and thereby sintered. In this way, a piezoelectric ceramic (crystal-oriented piezoelectric ceramic) having a composition formulated by externally adding 0.0005 mol of Mn to 1 mol of {Li_{0.065}(K_{0.45}Na_{0.55})_{0.935}}{Nb_{0.83}Ta_{0.09}Sb_{0.08}}O₃ was produced.

The sintering density and average orientation degree of the obtained piezoelectric ceramic were evaluated under the same conditions as in Example 1. As a result, the relative density of the piezoelectric ceramic of this Example was 95% or more. Also, the pseudo-cubic {100} plane was oriented in parallel to the tape plane, and the average orientation degree of the pseudo-cubic {100} plane according to the Lotgering's method reached up to 80.5%.

Subsequently, the obtained piezoelectric ceramic was ground, polished and machined to produce a ring-like piezoelectric ceramic having an outer diameter φ24 mm, an inner diameter φ16.4 mm and a thickness of 3 mm, with the top and bottom planes being parallel to the tape plane. On the top and bottom planes thereof, an Au electrode printing paste (ALP3057, produced by Sumitomo Metal Mining Co., Ltd.) was printed, dried and then baked at 850° C. for 10 minutes by using a mesh belt furnace to form an electrode having an outer diameter φ23 mm, an inner diameter φ17.4 mm and a thickness of 0.01 mm on the piezoelectric ceramic. Thereafter, a poling treatment was applied in the vertical direction to obtain a piezoelectric element where partial electrodes were formed on the piezoelectric ceramic.

The electrostatic capacitance and dielectric loss tan δ at room temperature (25° C.) of this piezoelectric element were measured and, as a result, the electrostatic capacitance was 802 pF and the dielectric loss tan δ was 2.1.

Subsequently, one electrode plate 4 with the insulating layer 5 facing down was externally fitted to the tubular shaft 2, and the piezoelectric element 3 and another electrode plate 4 with the insulating layer 5 facing up were superposed thereon. At this time, the paired electrode plates 4 and the piezoelectric element were arranged concentrically by using a jig, and a weight 6 was screwed together and fixed by fastening under a predetermined pressure. Thereafter, a resistor 12 was connected between lead parts 42 by electric resistance welding, and a connector 13 and a covering material 7 were formed by mold forming of a resin to produce a piezoelectric sensor 1.

Incidentally, the insulating layer may also be formed by coating an insulating material on the electrode plate, and the coating method includes the following.

1) A method of spraying insulating powder and applying curing treatment. Examples of this method include spray coating of an epoxy resin powder, and spray coating of a PPS powder.

2) A method of coating and curing a solvent-type insulating material. For example, a solvent-type acrylic resin is coated by spraying or the like.

3) A method of coating and curing a water-soluble insulating material. For example, a water-soluble acrylic resin is coated by spraying or the like.

4) A method of coating an acrylic resin by electrodeposition.

### Comparative Example 6

In this Example, a piezoelectric sensor using a piezoelectric ceramic comprising the same PZT material as in Comparative Example 3 is produced.

First, similarly to Comparative Example 3, a PbO power, a ZrO₂ powder, a TiO₂ powder, an SrTiO₃ powder and an Sb₂O₃ powder were weighed to give a (Pb_{0.95}Sr_{0.05}){(Zr_{0.53}Ti_{0.47})_{0.978}Sb_{0.022}}O₃ composition, and these powders were wet-mixed for 20 hours by using water as the medium and using Zr balls. The resulting mixed powder was then temporarily fired at 825° C. for 5 hours and further wet-ground by using water as the medium and using Zr balls. Subsequently, a binder (polyvinyl butyral) was added thereto to have a concentration of 1 wt % based on the temporarily fired powder material, and the slurry was then dried by a spray drier and granulated.

A binder (polyvinyl butyral) was added thereto to have a concentration of 1 wt % based on the temporarily fired powder material, and the slurry was then dried by a spray drier and granulated.

From this product, a ring-like powder compact having an outer diameter φ29 mm, an inner diameter φ10 mm and a thickness of 4 mm was obtained by dry press molding using a mold. Thereafter, the obtained ring-like powder compact was degreased in air. Furthermore, the ring-like powder compact after degreasing was placed on an MgO plate in an alumina sagger and sintered in air at 1,230° C. for 2 hours. In this way, a ring-shaped piezoelectric ceramic comprising (Pb_{0.95}Sr_{0.05}){(Zr_{0.53}Ti_{0.47})_{0.978}Sb_{0.022}}O₃ was produced.

Subsequently, the obtained piezoelectric ceramic was ground, polished and machined to produce a ring-like piezoelectric ceramic having an outer diameter φ24 mm, an inner diameter φ16.4 mm and a thickness of 3 mm, and on the top and bottom planes thereof, an Ag electrode printing paste was printed, dried and then baked at 750° C. for 10 minutes by using a mesh belt furnace to form an electrode having an outer diameter φ23 mm, an inner diameter φ17.4 mm and a thickness of 0.01 mm on the piezoelectric ceramic.

Thereafter, a poling treatment was applied in the vertical direction to obtain a piezoelectric element where partial electrodes were formed on the piezoelectric ceramic. By using this piezoelectric element, a piezoelectric sensor similar to that of Example 11 was produced.

### (Example 12) Temperature Characteristic of Electrostatic Capacitance

In this example, the fluctuation of the electrostatic capacitance in a fixed temperature range was evaluated for two kinds of piezoelectric elements produced in Example 11 and Comparative Example 6.

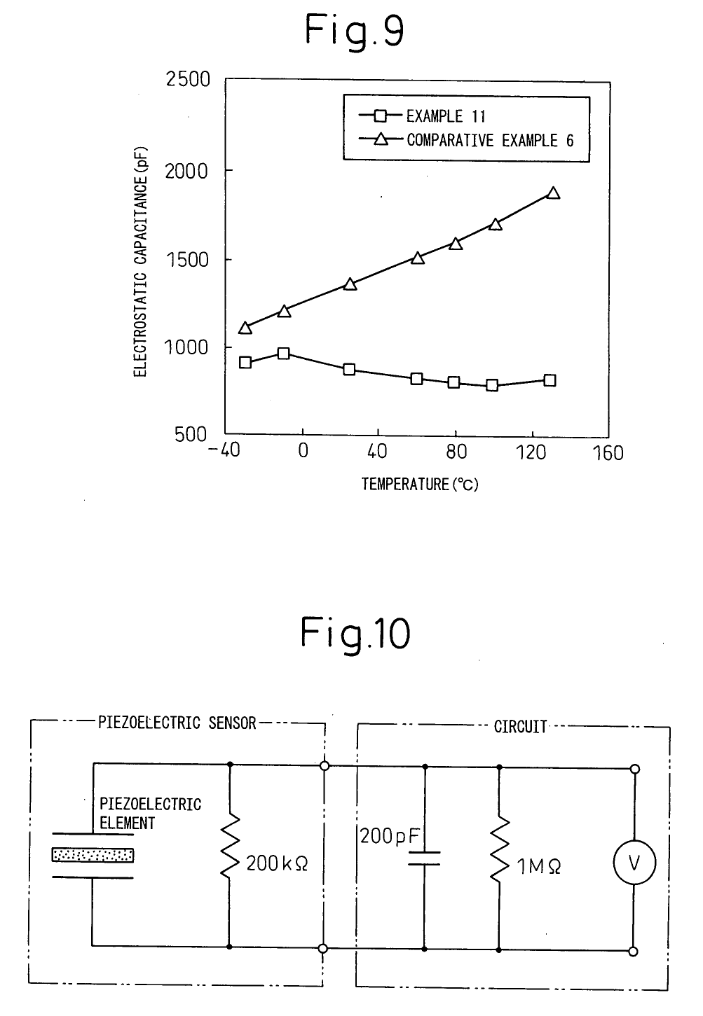

FIG. 9 shows the electrostatic capacitance in the temperature range from −30° C. to 130° C. of each of the piezoelectric elements of Example 11 and Comparative Example 6.

As seen from FIG. 9, the electrostatic capacitance of the piezoelectric element of Comparative Example 6 is increased in proportion to the temperature elevation and the fluctuation is large, whereas the electrostatic capacitance of the piezoelectric element of Example 11 has a small fluctuation with respect to the temperature change.

### (Example 13) Temperature Characteristic of Output Voltage

In this Example, the fluctuation of the output voltage in a fixed temperature range was evaluated for two kinds of piezoelectric sensor (non-resonance type knock sensor) produced in Example 11 and Comparative Example 6.

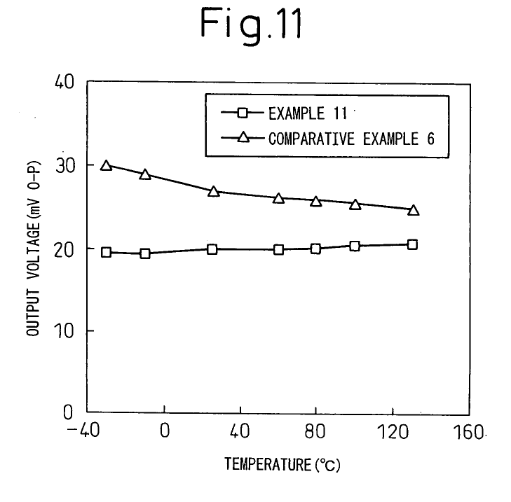

As for the output voltage, an electric charge generated when the knock sensor was vibrated in the up-down direction under the conditions of a frequency of an 8 kHz-sin wave and an acceleration of 1 G, was measured as the voltage in a circuit shown in FIG. 8. At this time, the thermal characteristic of the output voltage was examined by changing the temperature on the piezoelectric sensor side in the temperature range from −30° C. to 130° C. Incidentally, the measurement was performed in a state of constantly keeping the circuit part at a temperature of 25° C. FIG. 11 shows the results.

As seen from FIG. 11, the output voltage of the piezoelectric sensor of Comparative Example 6 is decreased along with the temperature elevation, whereas the output voltage of the piezoelectric sensor of Example 11 shows little fluctuation arising from the temperature change.

1. A piezoelectric sensor comprising a piezoelectric element and a holding member for holding said piezoelectric element, the piezoelectric element comprising a piezoelectric ceramic having formed on the surfaces thereof a pair of electrodes, wherein
said piezoelectric ceramic satisfies the following requirement (a) and/or requirement (b):
(a) in the temperature range from −30° C. to 160° C., the thermal expansion coefficient is 3.0 ppm/° C. or more, and
(b) in the temperature range from −30° C. to 160° C., the pyroelectric coefficient is 400 μCm⁻²K⁻¹ or less.

2. The piezoelectric sensor as claimed in claim 1, wherein in said piezoelectric ceramic, the piezoelectric constant g₃₁ in the temperature range from −30° C. to 80° C. is 0.006 Vm/N or more and the fluctuation of said piezoelectric constant g₃₁ in the temperature range from −30° C. to 80° C. is within ±15%.

3. The piezoelectric sensor as claimed in claim 1, wherein in said piezoelectric ceramic, the piezoelectric constant d₃₁ in the temperature range from −30° C. to 80° C. is 70 pC/N or more and the fluctuation of said piezoelectric constant d₃₁ in the temperature range from −30° C. to 80° C. is within ±15%.

4. The piezoelectric sensor as claimed in claim 1, wherein in said piezoelectric ceramic, the piezoelectric constant g₃₁ in the temperature range from −30° C. to 160° C. is 0.006 Vm/N or more and the fluctuation of said piezoelectric constant g₃₁ in the temperature range from −30° C. to 160° C. is within ±15%.

5. The piezoelectric sensor as claimed in claim 1, wherein in said piezoelectric ceramic, the piezoelectric constant d₃₁ in the temperature range from −30° C. to 160° C. is 70 pC/N or more and the fluctuation of said piezoelectric constant d₃₁ in the temperature range from −30° C. to 160° C. is within ±15%.

6. The piezoelectric sensor as claimed in claim 1, wherein said piezoelectric sensor is used for a knock sensor.

7. The piezoelectric sensor as claimed in claim 1, wherein said piezoelectric sensor is used for a pressure sensor, an acceleration sensor, a yaw rate sensor, a gyro sensor or a shock sensor.

8. The piezoelectric sensor as claimed in claim 1, wherein said piezoelectric sensor is a stacked piezoelectric sensor obtained by alternately stacking said piezoelectric ceramic and said electrode.

9. The piezoelectric sensor as claimed in claim 1, wherein said piezoelectric ceramic comprises a crystal-oriented piezoelectric ceramic comprising a polycrystalline body in which the main phase is an isotropic perovskite-type compound represented by the formula:
{Liₓ(K_{1-y}Na_{y})₁₋ₓ}{Nb_{1-z-w}Ta_{z}Sb_{w}}O₃
(wherein 0≦x≦0.2, 0≦y≦1, 0≦z≦0.4, 0≦w≦0.2 and x+z+w>0) and a specific crystal plane of each crystal grain constituting said polycrystalline body is oriented.

10. The piezoelectric sensor as claimed in claim 9, wherein in said crystal-oriented piezoelectric ceramic, x, y and z in the formula {Liₓ(K_{1-y}Na_{y})₁₋ₓ}{Nb_{1-z-w}Ta_{z}Sb_{w}}O₃ satisfy the relationships of the following formulae (1) and (2):
9x−5z−17w≧−318 (1)
−18.9x−3.9z−5.8w≦−130 (2)

11. The piezoelectric sensor as claimed in claim 9 wherein, in said crystal-oriented piezoelectric ceramic, the orientation degree of a pseudo-cubic {100} plane according to the Lotgering's method is 30% or more and the crystal system in the temperature range from 10° C. to 160° C. is tetragon.
